(19) United States
(12) Patent Application Publication
(10) Pub. No.: US 2026/0118602 A1
(43) Pub. Date: Apr. 30, 2026

(54) SEMICONDUCTOR PACKAGE INCLUDING OPTICAL STRUCTURE AND WAVEGUIDE

(71) Applicant: SAMSUNG ELECTRONICS CO., LTD., Suwon-si (KR)

(72) Inventor: Seok Geun Ahn, Suwon-si (KR)

(73) Assignee: SAMSUNG ELECTRONICS CO., LTD., Suwon-si (KR)

(21) Appl. No.: 19/186,094

(22) Filed: Apr. 22, 2025

(30) Foreign Application Priority Data
Oct. 28, 2024 (KR) 10-2024-0148718

(51) Int. Cl. G02B 6/42; H01L 23/498; H01L 25/16; H01L 23/00

(52) U.S. Cl. CPC G02B 6/4206; G02B 6/4214; H10W 70/635; H10W 90/00; H10W 90/701; H10W 74/15; H10W 90/724; H10W 90/734

(57) ABSTRACT

A semiconductor package includes: an optical structure; and a first transmission structure on the optical structure, in which the optical structure comprises a first waveguide extending in a first direction, in which the first transmission structure includes: a first bonding layer including a first portion and a second portion, and a second waveguide extending in the first direction, in which at least a first portion of the first waveguide overlaps a second portion of the second waveguide, in which the second portion of the first bonding layer is between the first waveguide and the second waveguide, and in which the first bonding layer includes a material different from the first waveguide and the second waveguide.

### CROSS-REFERENCE TO RELATED APPLICATIONS

This U.S. non-provisional patent application claims priority under 35 U.S.C. §119 to Korean Patent Application No. 10-2024-0148718, filed on October 28, 2024, in the Korean Intellectual Property Office, the entire contents of which are hereby incorporated by reference.

### BACKGROUND

The present disclosure relates to a semiconductor package, and in particular, to a semiconductor package including an optical structure and a waveguide.

The demand for the miniaturization and high-speed performance of electronic devices is increasing. Thus, studies are actively being conducted to replace conventional signal transmission via metal lines with methods using optical signals. To do this, a semiconductor package should be manufactured to include an optical integrated circuit with a light source and a light coupling device for generating and transmitting an optical signal. However, conventionally, an optical integrated circuit is connected to an optical bridge through an adhesive, resulting in instability. Furthermore, conventionally, a waveguide coupler is used to transmit light from the optical integrated circuit to the optical bridge, resulting in an optical loss.

### SUMMARY

One or more embodiments of the disclosure provides a semiconductor package with improved optical characteristics.

According to an aspect of the disclosure, a semiconductor package includes: an optical structure; and a first transmission structure on the optical structure, in which the optical structure comprises a first waveguide extending in a first direction, in which the first transmission structure includes: a first bonding layer including a first portion and a second portion, and a second waveguide extending in the first direction, in which at least a first portion of the first waveguide overlaps a second portion of the second waveguide, in which the second portion of the first bonding layer is between the first waveguide and the second waveguide, and in which the first bonding layer includes a material different from the first waveguide and the second waveguide.

According to an aspect of the disclosure, a semiconductor package includes: an optical structure; and a first transmission structure on the optical structure, in which the optical structure includes: a first waveguide extending in a first direction, and a first bonding layer on the first waveguide, in which the first transmission structure includes: a second bonding layer in contact with a surface of the first bonding layer, a second waveguide extending in the first direction, and a first transmissive layer on the second waveguide, in which at least a first portion of the first waveguide and overlaps a second portion of the second waveguide, and in which the first bonding layer and the second bonding layer comprise an inorganic insulating material.

According to an aspect of the disclosure, according to an aspect of the disclosure, a semiconductor package includes: a package substrate; a semiconductor chip on the package substrate; a first mold layer on the semiconductor chip; an optical structure on the package substrate; an electronic circuit structure on the optical structure; a first transmission structure and a second transmission structure on the optical structure; and a second mold layer on the electronic circuit structure, the optical structure, and the first transmission structure, the second mold layer spaced apart from the first mold layer, in which the optical structure comprises a first waveguide extending in a first direction, in which the first transmission structure comprises a second waveguide, which is extended in the first direction and is at a level higher than the first waveguide, in which the second transmission structure comprises a third waveguide, which is extended in the first direction and is at a level higher than the second waveguide, in which at least a first portion of the first waveguide overlaps a second portion of the second waveguide, and in which the third waveguide is spaced apart from the second waveguide in the first direction.

### BRIEF DESCRIPTION OF DRAWINGS

FIG. 1A is a plan view illustrating a semiconductor package according to one or more embodiments of the disclosure.

FIG. 1B is a sectional view taken along a line A1-A1’ of FIG. 1A.

FIG. 1C is an enlarged view illustrating a portion ‘B’ of FIG. 1B.

FIG. 1D is an enlarged view illustrating a portion ‘A’ of FIG. 1A.

FIG. 1E is a sectional view taken along a line B1-B1’ of FIG. 1D.

FIG. 1F is a sectional view taken along a line C1-C1’ of FIG. 1D.

FIGS. 2A, 2B, 2C, 2D, 2E, 2F, 2G, 2H, 2I, 2J, 2K, 2L, 2M, 2N, 2O, and 2P are diagrams illustrating a method of fabricating the semiconductor package of FIGS. 1A, 1B, 1C, 1D, 1E, and 1F.

FIG. 3 is an enlarged view illustrating a semiconductor package according to one or more embodiments of the disclosure.

FIGS. 4A, 4B, 4C, 4D, 4E, 4F, 4G, 4H, 4I, 4J, 4K, and 4L are diagrams illustrating a method of fabricating the semiconductor package of FIG. 3.

FIG. 5 is an enlarged view illustrating a semiconductor package according to one or more embodiments of the disclosure.

FIG. 6 is an enlarged view illustrating a semiconductor package according to one or more embodiments of the disclosure.

FIGS. 7A, 7B, 7C, and 7D are diagrams illustrating a semiconductor package according to one or more embodiments of the disclosure.

FIGS. 8A, 8B, 8C, and 8D are diagrams illustrating a semiconductor package according to one or more embodiments of the disclosure.

FIG. 9 is an enlarged view illustrating a semiconductor package according to one or more embodiments of the disclosure.

### DETAILED DESCRIPTION

Example embodiments of the disclosures will now be described more fully with reference to the accompanying drawings, in which example embodiments are shown.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

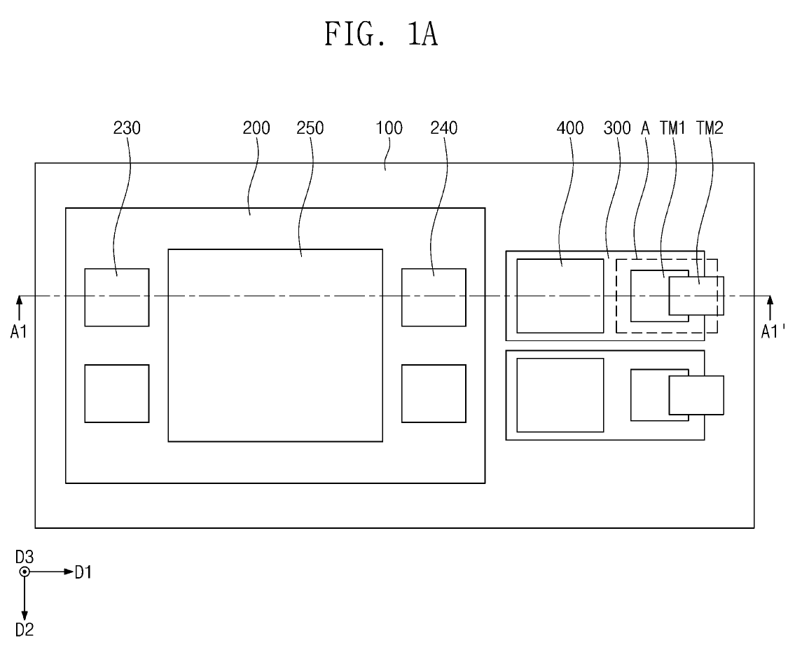

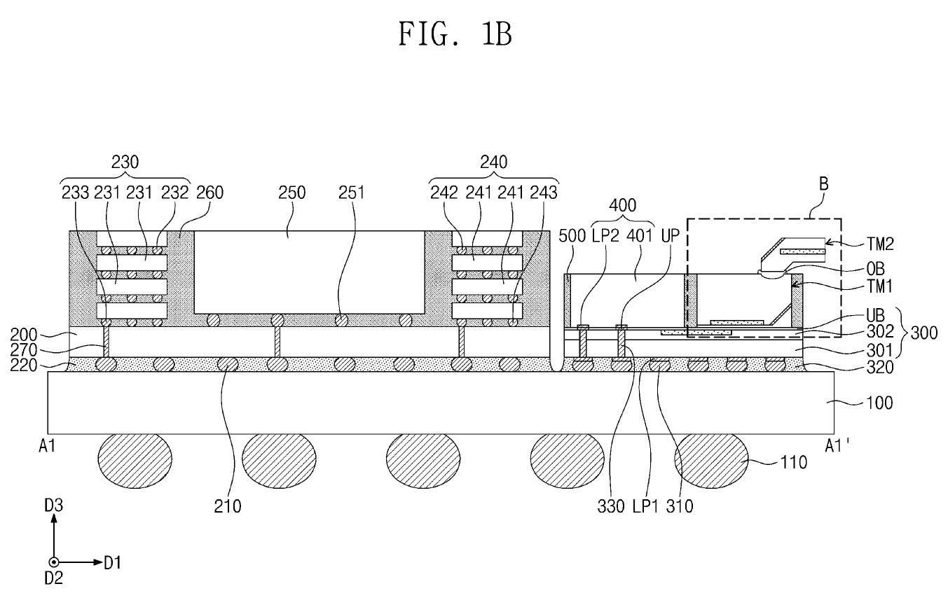

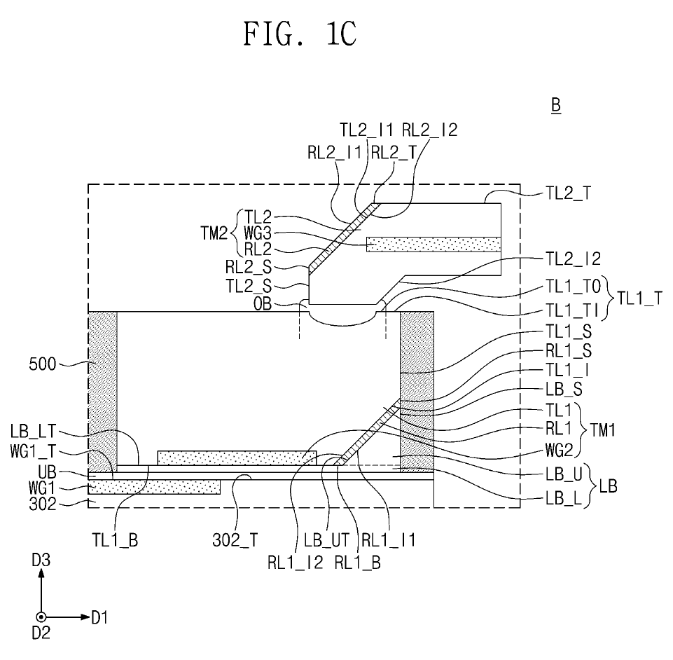

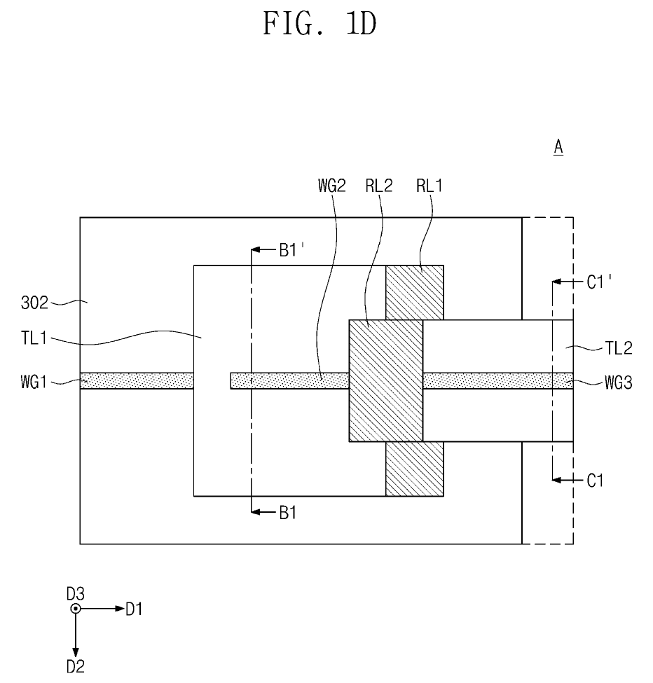

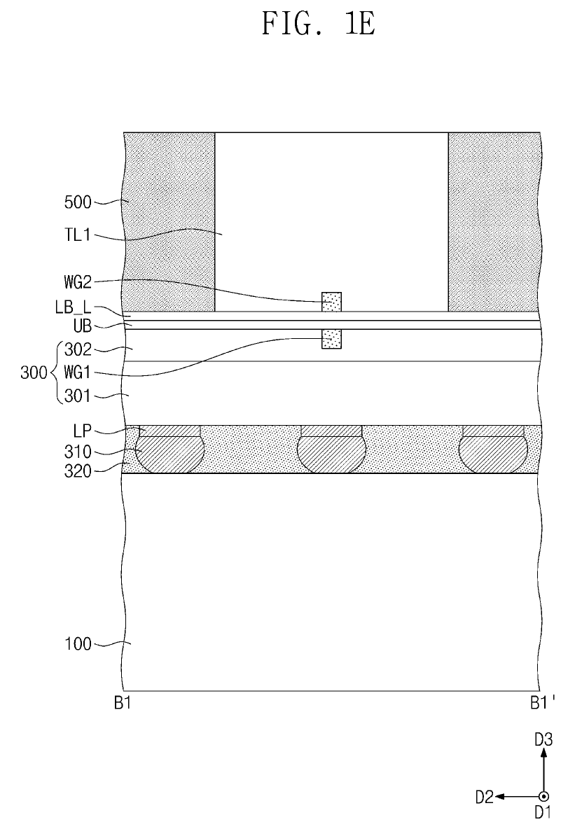

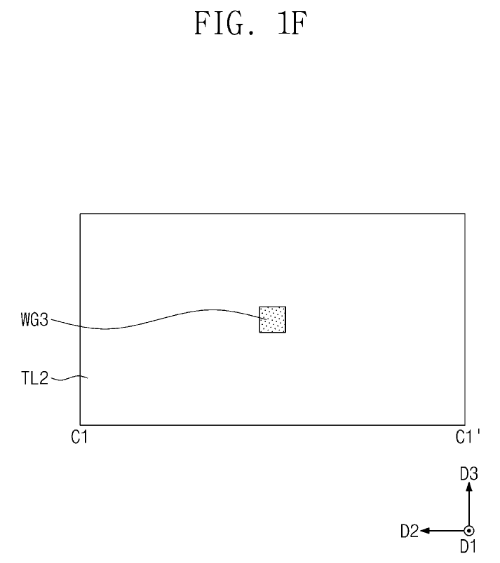

FIG. 1A is a plan view illustrating a semiconductor package according to one or more embodiments of the disclosure. FIG. 1B is a sectional view taken along a line A1-A1’ of FIG. 1A. FIG. 1C is an enlarged view illustrating a portion ‘B’ of FIG. 1B. FIG. 1D is an enlarged view illustrating a portion ‘A’ of FIG. 1A. FIG. 1E is a sectional view taken along a line B1-B1’ of FIG. 1D. FIG. 1F is a sectional view taken along a line C1-C1’ of FIG. 1D.

FIGS. 1A and 1B illustrate a package substrate 100 according to one or more embodiments. The package substrate 100 may be a plate-shaped structure, which is extended in a first direction D1 and a second direction D2. The first and second directions D1 and D2 may not be parallel to each other. For example, the first and second directions D1 and D2 may be horizontal directions that are orthogonal to each other.

The package substrate 100 may be, for example, a printed circuit board. A first solder ball 110 may be disposed on a bottom surface of the package substrate 100. The first solder ball 110 may include a conductive material. The first solder ball 110 may be electrically connected to the package substrate 100. In one or more embodiments, the package substrate 100 may be a redistribution substrate.

A connection substrate 200 may be disposed to be overlapped with the package substrate 100 in a third direction D3. The third direction D3 may not be parallel to the first and second directions D1 and D2. For example, the third direction D3 may be a vertical direction that is orthogonal to the first and second directions D1 and D2. The connection substrate 200 may be, for example, an interposer. A second solder ball 210 may be disposed between the package substrate 100 and the connection substrate 200. The second solder ball 210 may include a conductive material. The package substrate 100 and the connection substrate 200 may be electrically connected to each other by the second solder ball 210.

A first under-fill layer 220 may be disposed to surround the second solder ball 210. The first under-fill layer 220 may be in contact with a top surface of the package substrate 100 and a bottom surface of the connection substrate 200. In one or more examples, the under-fill layer 220 may be formed of material that fills gaps to improve reliability and protect electronic devices. The under-fill 220 may reduce strain on solder connections caused by difference in thermal expansion.

The first under-fill layer 220 may include an insulating material. For example, the first under-fill layer 220 may include a polymer material.

A first stack 230 and a second stack 240 may be disposed to be overlapped with the connection substrate 200 in the third direction D3. The first stack 230 may include first semiconductor chips 231, which are overlapped with each other in the third direction D3, first intermediate connectors 232, which are disposed between the first semiconductor chips 231, and first lower connectors 233, which are in contact with a top surface of the connection substrate 200.

The second stack 240 may include second semiconductor chips 241, which are overlapped with each other in the third direction D3, second intermediate connectors 242, which are disposed between the second semiconductor chips 241, and second lower connectors 243, which are in contact with the top surface of the connection substrate 200.

The first and second semiconductor chips 231 and 241 may be memory chips. For example, the first and second semiconductor chips 231 and 241 may be DRAM chips.

The first intermediate connectors 232, the second intermediate connectors 242, the first lower connectors 233, and the second lower connectors 243 may include at least one of conductive materials. The first semiconductor chips 231 may be electrically connected to each other through the first intermediate connectors 232. The second semiconductor chips 241 may be electrically connected to each other through the second intermediate connectors 242. The first semiconductor chips 231 may be electrically connected to the connection substrate 200 by the first lower connectors 233. The second semiconductor chips 241 may be electrically connected to the connection substrate 200 by the second lower connectors 243.

A third semiconductor chip 250 may be disposed between the first stack 230 and the second stack 240. The third semiconductor chip 250 may be a logic chip. Third lower connectors 251 may be disposed between the connection substrate 200 and the third semiconductor chip 250. The third lower connector 251 may include a conductive material. The third semiconductor chip 250 may be electrically connected to the connection substrate 200 by the third lower connectors 251.

A first mold layer 260 may be disposed to surround the first stack 230, the second stack 240, and the third semiconductor chip 250. The first mold layer 260 may include an insulating material. For example, the first mold layer 260 may include a polymer material.

First connection vias 270 may be formed to penetrate the connection substrate 200. The first connection vias 270 may include a conductive material. The first stack 230, the second stack 240, and the semiconductor chips 250 may be electrically connected to the second solder balls 210 by the first connection vias 270.

An optical structure 300 may be disposed to be overlapped with the package substrate 100 in the third direction D3. The optical structure 300 may include a photo integrated circuit (PIC). The PIC may include a phase modulator. The PIC may be a microchip containing two or more photonic components that form a functioning circuit that detects, generates, transports, and processes light. The PIC may use photons (or particles of light) as opposed to electrons that are used by electronic integrated circuits. For example, PIC may provide functions for information signals imposed on optical wavelengths typically in the visible spectrum or near-infrared (850–1650 nm).

The optical structure 300 may include a base layer 301, an optical path layer 302 on the base layer 301, and an upper bonding layer UB on the optical path layer 302. The base layer 301 may include a semiconductor substrate and a redistribution layer. The redistribution layer may include a plurality of interconnection lines and a plurality of vias.

A first lower pad LP1 may be disposed to be in contact with a bottom surface of the base layer 301. A third solder ball 310 may be disposed to be in contact with a bottom surface of the first lower pad LP1. The first lower pad LP1 and the third solder ball 310 may include at least one of conductive materials. The base layer 301 may be electrically connected to the package substrate 100 through the first lower pad LP1 and the third solder ball 310.

A second under-fill layer 320 may be disposed between the base layer 301 and the package substrate 100. The second under-fill layer 320 may enclose a lower pad LP and the third solder ball 310. The second under-fill layer 320 may include an insulating material. For example, the second under-fill layer 320 may include a polymer material.

The optical structure 300 may further include an upper pad UP. The upper bonding layer UB may enclose the upper pad UP. A thickness of the upper bonding layer UB in the third direction D3 may be smaller than a thickness of the optical path layer 302 in the third direction D3. The upper pad UP may include a conductive material. The upper bonding layer UB may enclose the upper pad UP.

Second connection vias 330 may be disposed to penetrate the optical path layer 302 and the base layer 301. The second connection vias 330 may include a conductive material. The upper pad UP and the first lower pad LP1 may be electrically connected to each other by the second connection vias 330.

An electronic circuit structure 400 may be disposed on the upper bonding layer UB. The electronic circuit structure 400 may include an electronic integrated circuit (EIC). In one or more examples, the EIC may be a set of electronic circuits formed of various electronic components (e.g., transistors, resistors, capacitors, etc.) to perform various functions such as processing and storing information. The electronic circuit structure 400 may include a circuit layer 401 and a second lower pad LP2. The circuit layer 401 may include a semiconductor substrate and a redistribution layer. The redistribution layer may include a plurality of vias and a plurality of interconnection lines.

The second lower pad LP2 may be in contact with a top surface of the upper pad UP. The second lower pad LP2 and the upper pad UP may be electrically connected to each other. The circuit layer 401 may be electrically connected to the upper pad UP by the second lower pad LP2. The second lower pad LP2 and the upper pad UP may be bonded to each other.

A first transmission structure TM1 may be disposed on the upper bonding layer UB. A second transmission structure TM2 may be disposed to be overlapped with the first transmission structure TM1 in the third direction D3. An optical adhesive layer OB may be disposed to be in contact with the first and second transmission structures TM1 and TM2. In one or more embodiments, the optical adhesive layer OB may include a polymer material.

A second mold layer 500 may be disposed to be in contact with the electronic circuit structure 400, the first transmission structure TM1, and the upper bonding layer UB. The first mold layer 260 and the second mold layer 500 may be spaced apart from each other in the first direction D1.

Referring to FIGS. 1C, 1D, 1E, and 1F, the optical structure 300 may further include a first waveguide WG1. As understood by one of ordinary skill in the art, a waveguide may be a structure that guides electromagnetic waves in the optical spectrum. For example, an electromagnetic wave, once trapped inside the medium with higher index, propagates along the waveguide and may be confined by total internal reflection. Accordingly, light launched into the waveguide at the input position will be transmitted through the structure and emerge at the output position The first waveguide WG1 may be disposed on the optical path layer 302. The first waveguide WG1 may be extended in the first direction D1. Side and bottom surfaces of the first waveguide WG1 may be in contact with the optical path layer 302. In one or more embodiments, the first waveguide WG1 may have a rectangular shape, when viewed in the sectional view of FIG. 1E. In one or more embodiments, the first waveguide WG1 may have a circular or hexagonal shape, when viewed in the sectional view of FIG. 1E. In one or more embodiments, a top surface WG1_T of the first waveguide WG1 may be in contact with a bottom surface of the upper bonding layer UB.

The first waveguide WG1 may include a material different from the optical path layer 302. The first waveguide WG1 may include a material having a higher refractive index than the optical path layer 302. The first waveguide WG1 may include a material having a refractive index ranging from 1.9 to 2.2. For example, the optical path layer 302 may include SiO₂, and the first waveguide WG1 may include SiN.

The top surface WG1_T of the first waveguide WG1 and a top surface 302_T of the optical path layer 302 may be coplanar with each other. In one or more embodiments, the optical path layer 302 may cover the top surface WG1_T of the first waveguide WG1.

The upper bonding layer UB may be disposed on the top surface WG1_T of the first waveguide WG1 and the top surface 302_T of the optical path layer 302. A bottom surface UB_B of the upper bonding layer UB may be in contact with the top surface WG1_T of the first waveguide WG1 and the top surface 302_T of the optical path layer 302. In one or more embodiments, a portion of the optical path layer 302 may be disposed between the bottom surface of the upper bonding layer UB and the top surface WG1_T of the first waveguide WG1, and the bottom surface of the upper bonding layer UB and the top surface WG1_T of the first waveguide WG1 may be spaced apart from each other by the portion of the optical path layer 302.

The first transmission structure TM1 may include a lower bonding layer LB, a second waveguide WG2, a first reflection layer RL1, and a first transmissive layer TL1.

The lower bonding layer LB may include a lower portion LB_L, which is in contact with a top surface of the upper bonding layer UB, and an upper portion LB_U, which is disposed at a level higher than the lower portion LB_L. The lower bonding layer LB may include the same material as the upper bonding layer UB.

The upper bonding layer UB and the lower portion LB_L of the lower bonding layer LB may be disposed between the first waveguide WG1 and the second waveguide WG2.

A top surface LB_UT of the upper portion LB_U of the lower bonding layer LB may be connected to a top surface LB_LT of the lower portion LB_L of the lower bonding layer LB. The top surface LB_UT of the upper portion LB_U of the lower bonding layer LB may be inclined to the top surface LB_LT of the lower portion LB_L of the lower bonding layer LB. A side surface LB_S of the lower bonding layer LB may be in contact with the second mold layer 500.

A thickness of the upper portion LB_U of the lower bonding layer LB in the third direction D3 may be larger than a thickness of the lower portion LB_L of the lower bonding layer LB in the third direction D3. The upper and lower bonding layers UB and LB may be bonded to each other.

The second waveguide WG2 may be extended in the first direction D1. The second waveguide WG2 may be disposed at a level higher than the first waveguide WG1. The second waveguide WG2 may be disposed at the same level as the first reflection layer RL1 and the upper portion LB_U of the lower bonding layer LB. The second waveguide WG2 may be overlapped with the first waveguide WG1 in the third direction D3. The second waveguide WG2 may be spaced apart from the first waveguide WG1 in the third direction D3.

In one or more embodiments, the second waveguide WG2 may include the same material as the first waveguide WG1. The second waveguide WG2 may include a material having the same refractive index as the first waveguide WG1. For example, the second waveguide WG2 may include a material having a refractive index ranging from 1.9 to 2.2. For example, the second waveguide WG2 may include SiN. However, as understood by one of ordinary skill in the art, the embodiments are not limited to this configuration, and the second waveguide WG2 may include a material different from the first waveguide WG1.

The first reflection layer RL1 may be in contact with the lower portion LB_L and the upper portion LB_U of the lower bonding layer LB. The first reflection layer RL1 may be spaced apart from the second waveguide WG2 in the first direction D1. The first reflection layer RL1 may include a first inclined surface RL1_I1 in contact with the top surface LB_UT of the upper portion LB_U of the lower bonding layer LB. The inclined surface RL1_I1 of the first reflection layer RL1 may connect a side surface RL1_S and a bottom surface RL1_B of the first reflection layer RL1 to each other.

The first reflection layer RL1 may include a second inclined surface RL1_I2, which connects the side surface RL1_S and the bottom surface RL1_B of the first reflection layer RL1 and is spaced apart from the upper portion LB_U of the lower bonding layer LB. The first inclined surface RL1_I1 and the second inclined surface RL1_I2 of the first reflection layer RL1 may be inclined to the bottom surface RL1_B of the first reflection layer RL1. The side surface RL1_S of the first reflection layer RL1 may be in contact with the second mold layer 500.

The first reflection layer RL1 may include a material having a refractive index ranging from 1 to 2. For example, the first reflection layer RL1 may be formed of or include Au, Ti, or TiO₂.

The first transmissive layer TL1 may cover the second inclined surface RL1_I2 of the first reflection layer RL1, the second waveguide WG2, and the lower portion LB_L of the lower bonding layer LB. A bottom surface TL1_B of the first transmissive layer TL1 may be in contact with the top surface LB_LT of the lower portion LB_L of the lower bonding layer LB. A side surface TL1_S of the first transmissive layer TL1 may be in contact with the second mold layer 500. The first transmissive layer TL1 may include an inclined surface TL1_I connecting the side surface TL1_S and the bottom surface TL1_B of the first transmissive layer TL1. The inclined surface TL1_I of the first transmissive layer TL1 may be inclined to the bottom surface TL1_B of the first transmissive layer TL1. The inclined surface TL1_I of the first transmissive layer TL1 may be in contact with the first inclined surface RL1_I1 of the first reflection layer RL1.

A top surface TL1_T of the first transmissive layer TL1 may include an inner portion TL1_TI and an outer portion TL1_TO surrounding the inner portion TL1_TI. The inner portion TL1_TI of the top surface TL1_T of the first transmissive layer TL1 may include a curved surface. The inner portion TL1_TI of the top surface TL1_T of the first transmissive layer TL1 may include a curved surface that is concave toward the bottom surface TL1_B of the first transmissive layer TL1. In one or more embodiments, the inner portion TL1_TI of the top surface TL1_T of the first transmissive layer TL1 may include a curved surface that is convex toward the second transmission structure TM2.

The side surface TL1_S of the first transmissive layer TL1, the side surface RL1_S of the first reflection layer RL1, and the side surface LB_S of the lower bonding layer LB may be coplanar with each other.

The optical adhesive layer OB may be in contact with the inner portion TL1_TI of the top surface TL1_T of the first transmissive layer TL1. The optical adhesive layer OB may be in contact with the curved surface of the inner portion TL1_TI of the top surface TL1_T of the first transmissive layer TL1.

The second transmission structure TM2 may include a second reflection layer RL2, a second transmissive layer TL2, and a third waveguide WG3. The optical adhesive layer OB may be overlapped with the first reflection layer RL1 and the second reflection layer RL2 in the third direction D3. A bottom surface of the second transmissive layer TL2 may be placed at a level lower than a top surface of the optical adhesive layer OB. The second transmissive layer TL2 may be provided to penetrate the top surface of the optical adhesive layer OB.

The second transmissive layer TL2 may include a first inclined surface TL2_I1 connecting a top surface TL2_T and a side surface TL2_S. The first inclined surface TL2_I1 of the second transmissive layer TL2 may be inclined to the top surface TL2_T of the second transmissive layer TL2. The second transmissive layer TL2 may include a second inclined surface TL2_I2, which is spaced apart from the top surface TL2_T and the side surface TL2_S.

The second reflection layer RL2 may be in contact with the first inclined surface TL2_I1 of the second transmissive layer TL2. The second reflection layer RL2 may include a top surface RL2_T, a side surface RL_S, and a first inclined surface RL2_I1, which connects the top surface RL2_T to the side surface RL_S and is in contact with the first inclined surface TL2_I1 of the second transmissive layer TL2. The second reflection layer RL2 may include a material having a refractive index ranging from 1 to 2. For example, the second reflection layer RL2 may include Au, Ti, or TiO₂. The second reflection layer RL2 may include the same material as the first reflection layer RL1. The second reflection layer RL2 may be overlapped with the first reflection layer RL1 in the third direction D3.

The third waveguide WG3 may be disposed at a level higher than the first and second waveguides WG1 and WG2. The third waveguide WG3 may be disposed at the same level as the second reflection layer RL2. The third waveguide WG3 may be spaced apart from the second reflection layer RL2 in the first direction D1. The third waveguide WG3 may be extended in the first direction D1.

The third waveguide WG3 may not be overlapped with the first and second waveguides WG1 and WG2 in the third direction D3. The third waveguide WG3 may be spaced apart from the first and second waveguides WG1 and WG2 in the first direction D1.

The optical path layer 302 and the first waveguide WG1 may include different materials from each other. For example, the optical path layer 302 may include SiO₂, and the first waveguide WG1 may include SiN. For example, the optical path layer 302 may include glass, and the first waveguide WG1 may be formed of or include glass or SiN that has a crystal structure and a refractive index different from the optical path layer 302.

The upper bonding layer UB may include an inorganic insulating material. For example, the upper bonding layer UB may include SiO₂ or SiCN. The first waveguide WG1 and the upper bonding layer UB may include different materials from each other. For example, the upper bonding layer UB may include SiO₂ or SiCN, and the first waveguide WG1 may include glass or SiN.

The lower bonding layer LB may include the same material as the upper bonding layer UB. For example, the upper and lower bonding layers UB and LB may include SiO₂ or SiCN.

The second waveguide WG2 and the first transmissive layer TL1 may include materials different from each other. For example, the first transmissive layer TL1 may include Si, and the second waveguide WG2 may include SiN. For example, the first transmissive layer TL1 may include glass, and the second waveguide WG2 may include glass or SiN that has a crystal structure and a refractive index different from the first transmissive layer TL1.

The third waveguide WG3 and the second transmissive layer TL2 may include different materials from each other. For example, the second transmissive layer TL2 may include Si, and the third waveguide WG3 may include SiN. For example, the second transmissive layer TL2 may include glass, and the third waveguide WG3 may be formed of or include glass or SiN that has a crystal structure and a refractive index different from the second transmissive layer TL2.

In one or more embodiments, the first transmissive layer TL1, the second transmissive layer TL2, and the optical path layer 302 may include glass, and the first waveguide WG1, the second waveguide WG2, and the third waveguide WG3 may include the same material.

In one or more embodiments, the first transmissive layer TL1 and the second transmissive layer TL2 may include Si, the optical path layer 302 may include SiO₂, and the first waveguide WG1, the second waveguide WG2, and the third waveguide WG3 may include the same material.

In the semiconductor package according to one or more embodiments of the disclosure, each of the upper and lower bonding layers UB and LB may include an oxide material and may be bonded to each other through a bonding process. Thus, each of the upper and lower bonding layers UB and LB may have a relatively small thickness. A distance between the first and second waveguides WG1 and WG2 may be relatively small, and light may be transmitted from the first waveguide WG1 to the second waveguide WG2 through evanescent coupling.

In the semiconductor package according to one or more embodiments of the disclosure, each of the upper and lower bonding layers UB and LB may include an oxide material and may be bonded to each other through a bonding process. Thus, when light is transmitted from the first waveguide WG1 to the second waveguide WG2, an optical loss in the upper and lower bonding layers UB and LB may be reduced.

In the semiconductor package according to one or more embodiments of the disclosure, the first reflection layer RL1 may include the first inclined surface RL1_I1, the second reflection layer RL2 may include the first inclined surface RL2_I1, and light emitted from the second waveguide WG2 may be transmitted to the third waveguide WG3 that is placed at a level higher than the second waveguide WG2. Accordingly, light emitted from the optical structure 300 may be received through the third waveguide WG3 spaced apart from the optical structure 300.

In the semiconductor package according to one or more embodiments of the disclosure, a bottom surface of the optical adhesive layer OB and the top surface TL1_T of the first transmissive layer TL1 may include a curved surface, and in this case, the optical adhesive layer OB may serve as a lens. Thus, an intensity of light, which is incident to the second reflection layer RL2 and the third waveguide WG3, may be relatively increased.

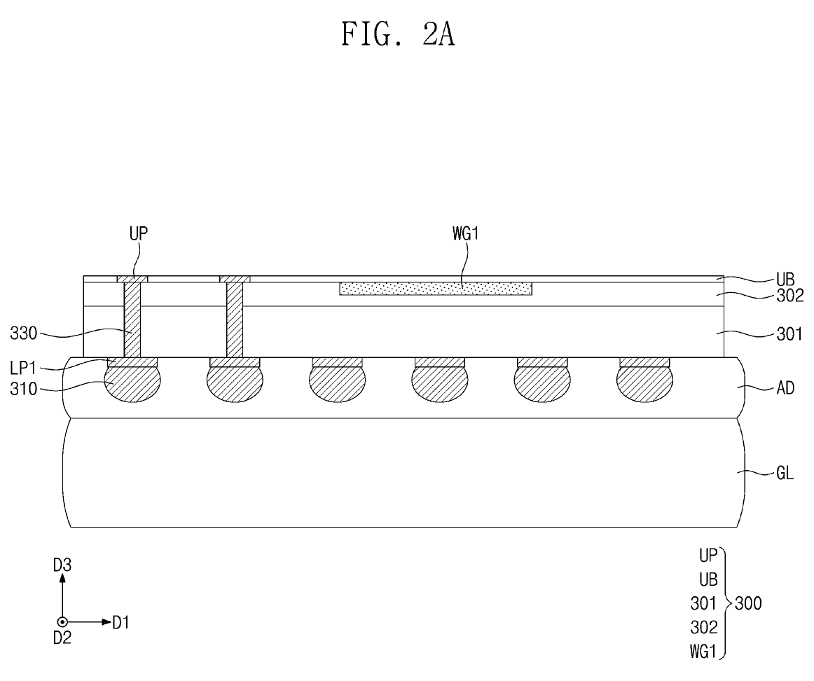

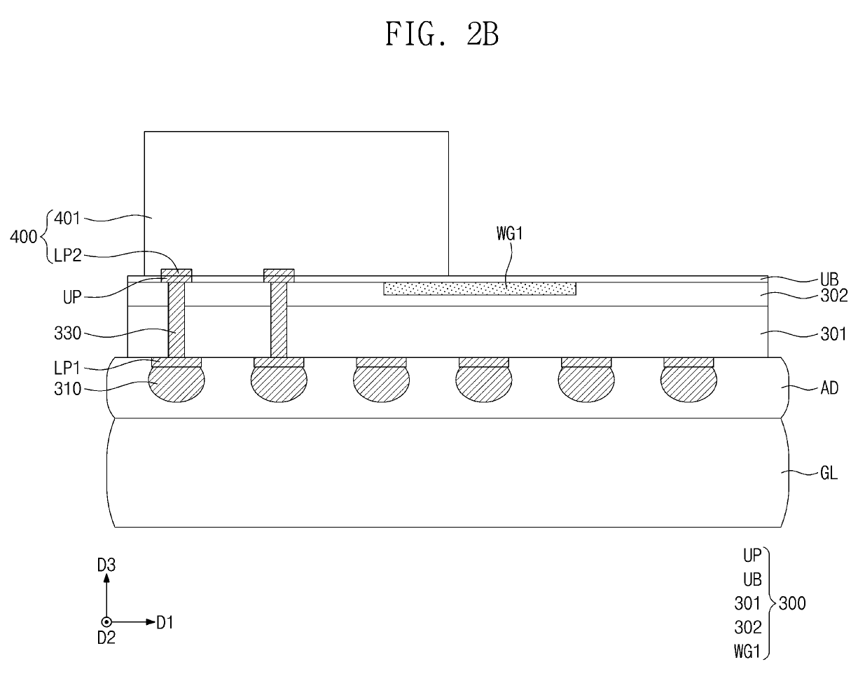

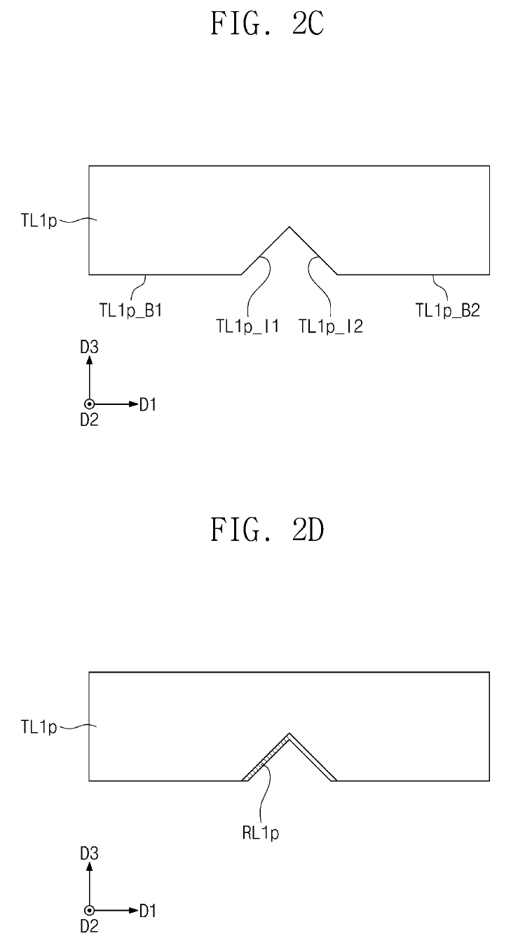

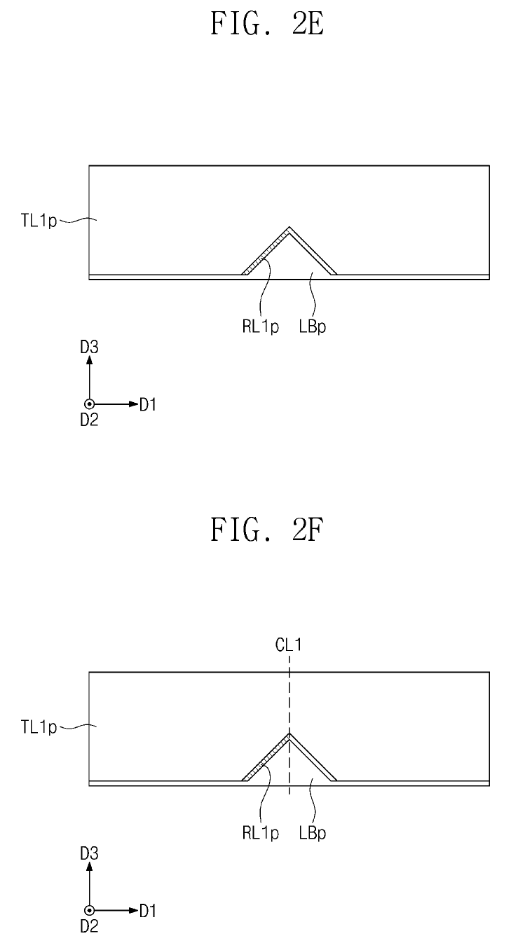

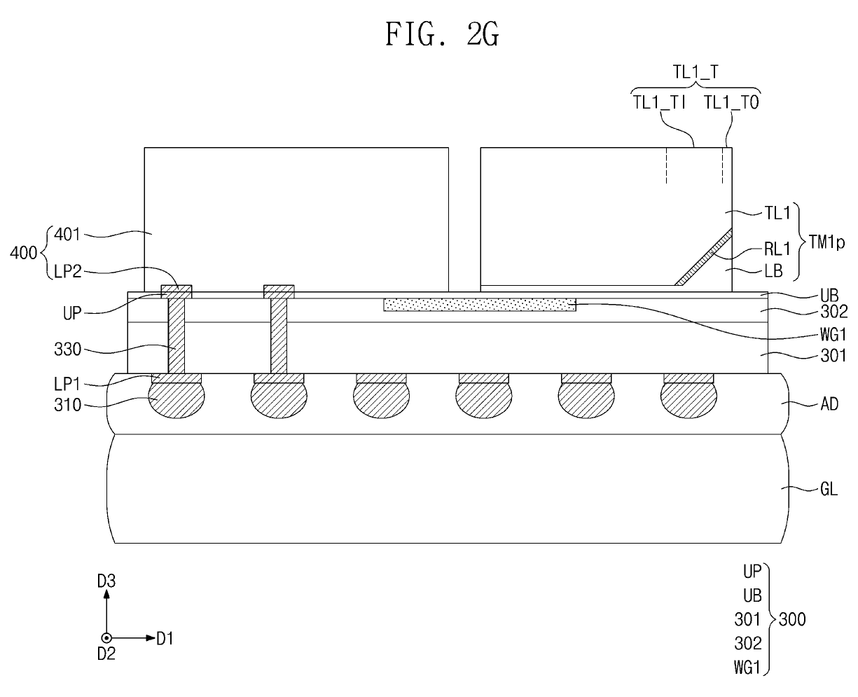

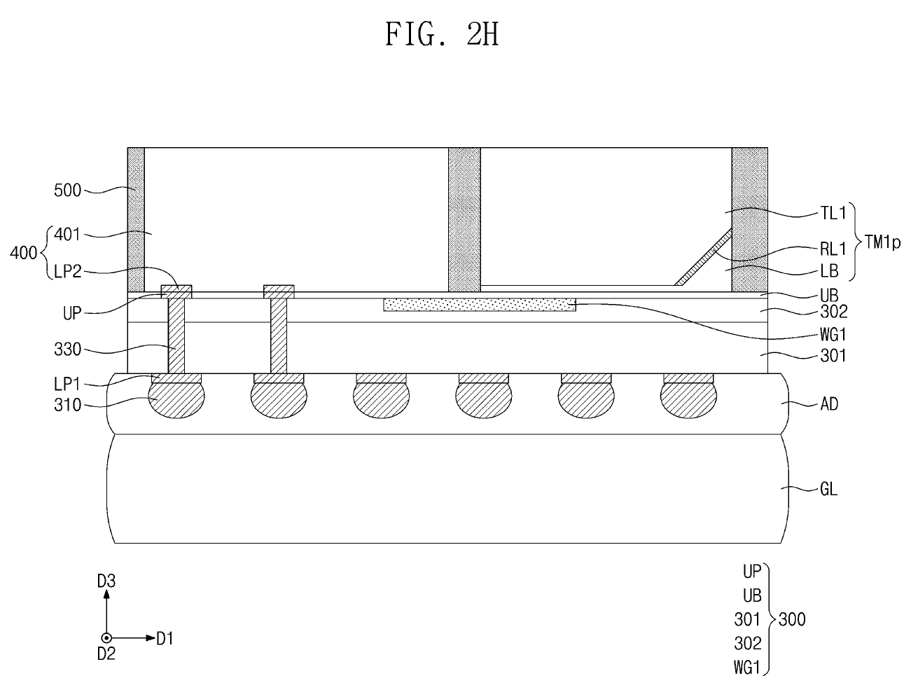

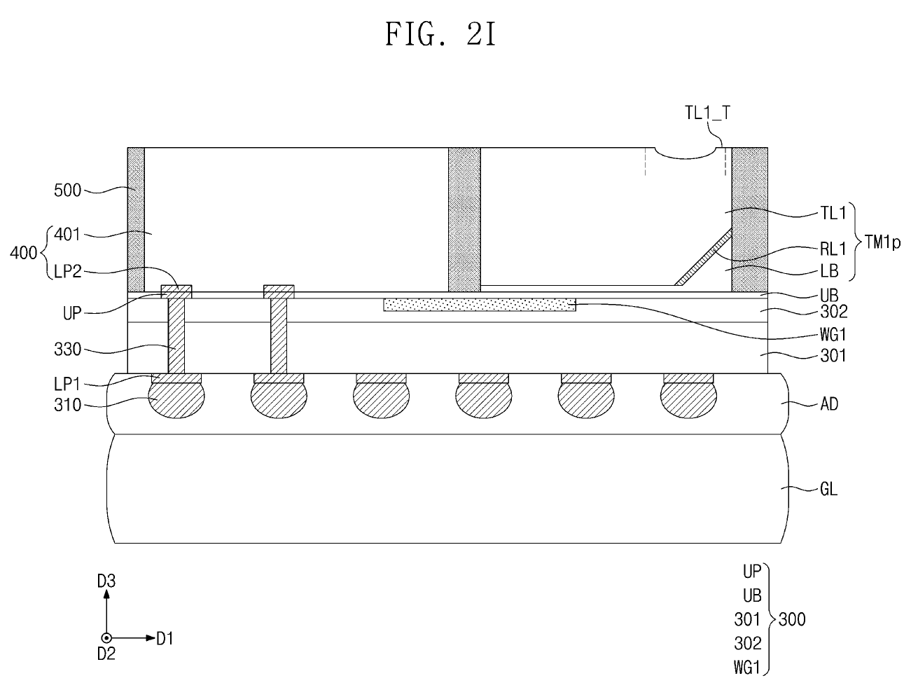

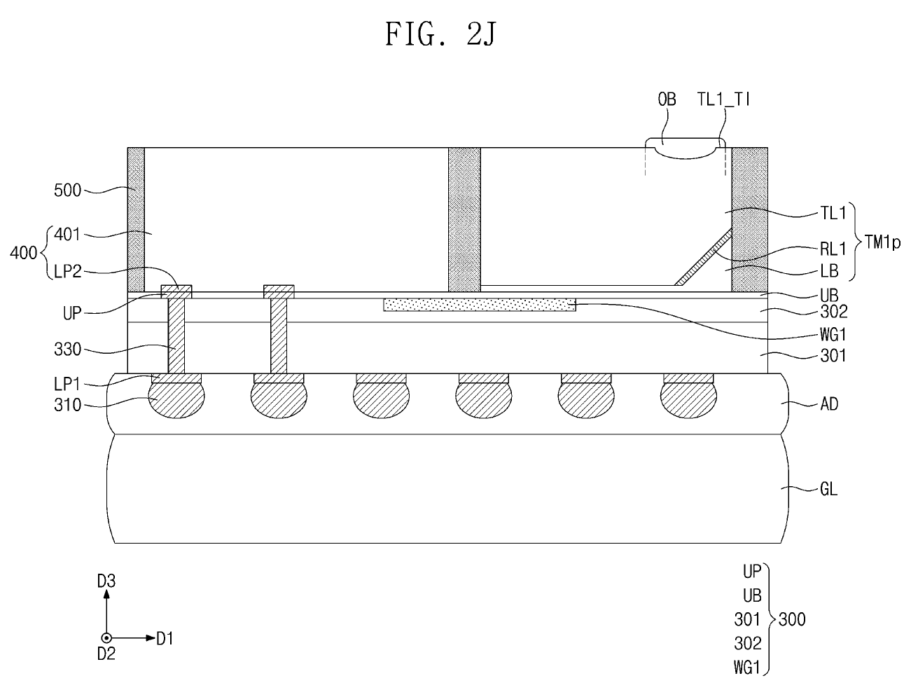

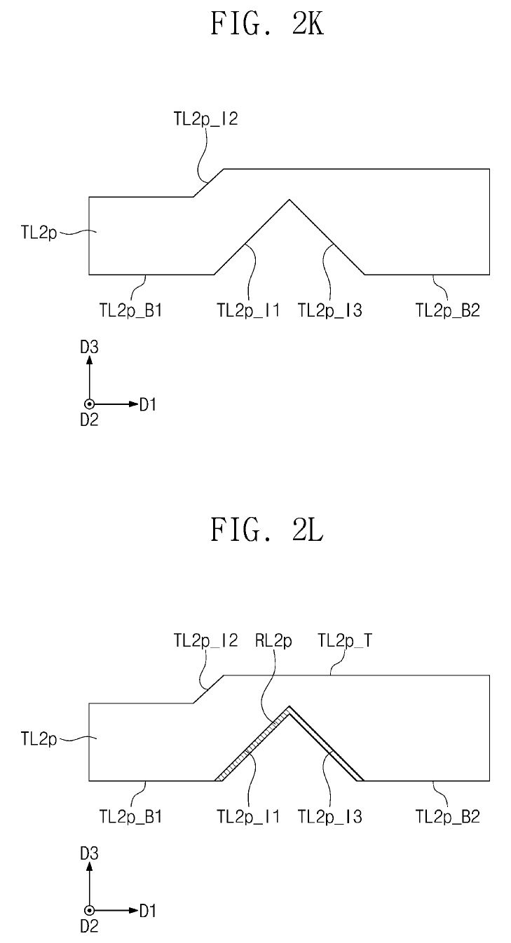

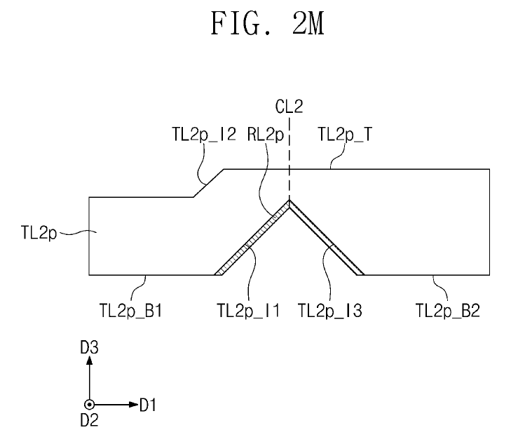

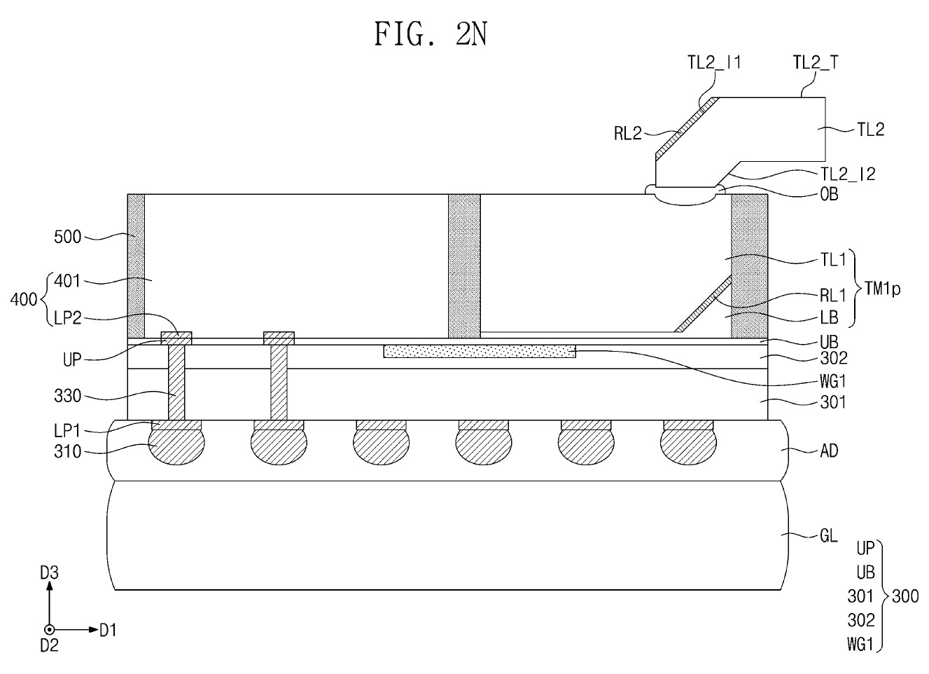

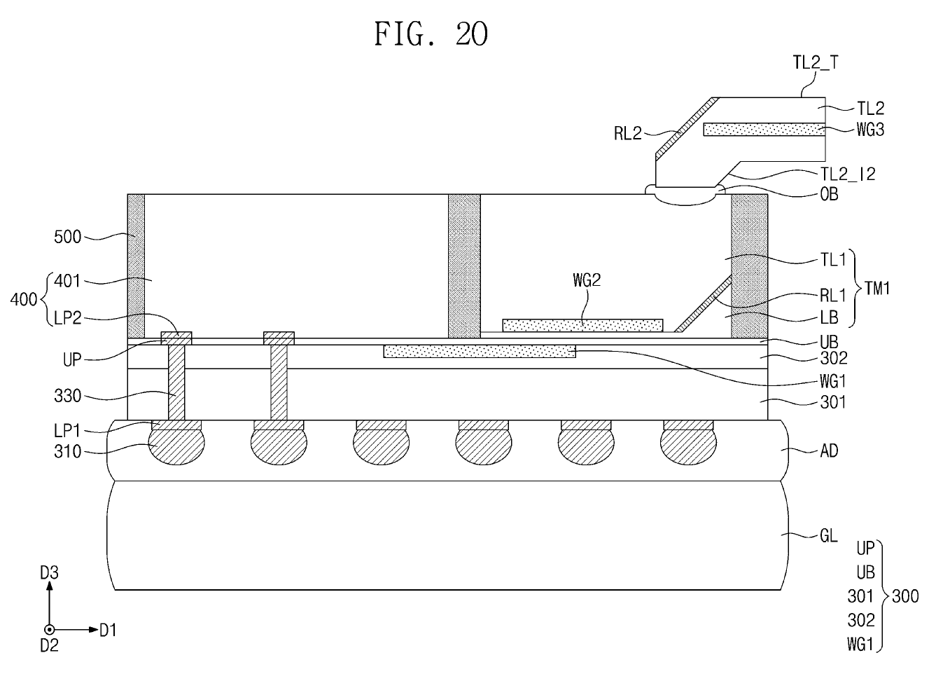

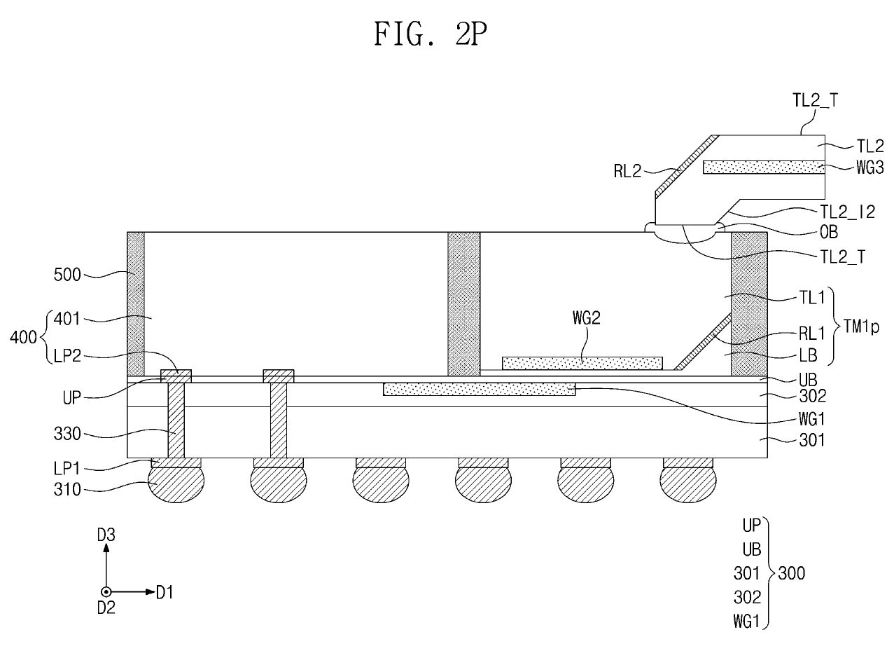

FIGS. 2A, 2B, 2C, 2D, 2E, 2F, 2G, 2H, 2I, 2J, 2K, 2L, 2M, 2N, 2O, and 2P are diagrams illustrating a method of fabricating the semiconductor package of FIGS. 1A, 1B, 1C, 1D, 1E, and 1F.

Referring to FIG. 2A, an adhesive layer AD, the third solder ball 310, the first lower pad LP1, and the optical structure 300 may be sequentially formed on a base substrate GL.

In one or more embodiments, the optical path layer 302 may include glass, and the formation of the first waveguide WG1 may include performing a laser direct writing process. For example, the optical path layer 302 may be irradiated with a laser beam, and a portion of the optical path layer 302 irradiated with the laser beam may have a changed crystal structure and a changed refractive index. The portion of the optical path layer 302 irradiated with the laser beam may be defined as the first waveguide WG1.

In one or more embodiments, the optical path layer 302 may include SiO₂, and the formation of the first waveguide WG1 may include etching the optical path layer 302 and depositing a SiN layer on the etched optical path layer 302 to form the first waveguide WG1.

The base substrate GL may include glass. The adhesive layer AD may include a polymer material. The adhesive layer AD may enclose the third solder ball 310 and the first lower pad LP1.

Referring to FIG. 2B, the electronic circuit structure 400 may be formed on the upper bonding layer UB and the upper pad UP. The formation of the electronic circuit structure 400 on the upper bonding layer UB and the upper pad UP may include performing a bonding process.

Referring to FIG. 2C, a first preliminary transmissive layer TL1p may be provided. A bottom surface of the first preliminary transmissive layer TL1p may include a first flat surface TL1p_B1, a second flat surface TL1p_B2, a first inclined surface TL1p_I1, and a second inclined surface TL1p_I2.

The first inclined surface TL1p_I1 of the first preliminary transmissive layer TL1p may be connected to the first flat surface TL1p_B1. The first inclined surface TL1p_I1 of the first preliminary transmissive layer TL1p may be connected to the first flat surface TL1p_B1. The second inclined surface TL1p_I2 of the first preliminary transmissive layer TL1p may be connected to the second flat surface TL1p_B2. The first inclined surface TL1p_I1 and the second inclined surface TL1p_I2 of the first preliminary transmissive layer TL1p may be connected to each other. The first inclined surface TL1p_I1 of the first preliminary transmissive layer TL1p may be inclined to the first flat surface TL1p_B1. The second inclined surface TL1p_I2 of the first preliminary transmissive layer TL1p may be inclined to the second flat surface TL1p_B2.

Referring to FIG. 2D, a first preliminary reflection layer RL1p may be formed on the first inclined surface TL1p_I1 and the second inclined surface TL1p_I2 of the first preliminary transmissive layer TL1p. The formation of the first preliminary reflection layer RL1p may include performing a chemical vapor deposition (CVD) process.

Referring to FIG. 2E, a preliminary lower bonding layer LBp may be formed. The formation of the preliminary lower bonding layer LBp may include performing a chemical vapor deposition (CVD) process.

Referring to FIG. 2F, a cutting process may be performed on the first preliminary transmissive layer TL1p, the preliminary lower bonding layer LBp, and the first preliminary reflection layer RL1p. The first preliminary transmissive layer TL1p, the preliminary lower bonding layer LBp, and the first preliminary reflection layer RL1p may be cut along a first cutting line CL1.

Referring to FIG. 2G, the first transmissive layer TL1, the lower bonding layer LB, and the first reflection layer RL1 may be respectively defined by performing the cutting process on the first preliminary transmissive layer TL1p, the preliminary lower bonding layer LBp, and the first preliminary reflection layer RL1p. A first preliminary transmission structure TM1p may include the first transmissive layer TL1, the lower bonding layer LB, and the first reflection layer RL1.

The first preliminary transmission structure TM1p may be provided on the upper bonding layer UB. The providing of the first preliminary transmission structure TM1p on the upper bonding layer UB may include performing a bonding process.

Referring to FIG. 2H, the second mold layer 500 may be formed.

Referring to FIG. 2I, a portion of the first preliminary transmission structure TM1p may be removed. The partial removal of the first preliminary transmission structure TM1p may include performing an etching process. As a result of the partial removal of the first preliminary transmission structure TM1p, a portion of an inner portion TM1p_TI of a top surface TM1p_T of the first preliminary transmission structure TM1p may be formed to have a curved surface.

Referring to FIG. 2J, the optical adhesive layer OB may be formed.

Referring to FIG. 2K, a second preliminary transmissive layer TL2p may be provided. A bottom surface of the second preliminary transmissive layer TL2p may include a first flat surface TL2p_B1 and a second flat surface TL2p_B2, which are spaced apart from each other in the first direction D1. The second preliminary transmissive layer TL2p may include a first inclined surface TL2p_I1 connected to the first flat surface TL2p_B1, a second inclined surface TL2p_I2 connected to a top surface TL2p_T, and a third inclined surface TL2p_I3 connected to the second flat surface TL2p_B2. The first and third inclined surfaces TL2p_I1 and TL2p_I3 of the second preliminary transmissive layer TL2p may be connected to each other. The first inclined surface TL2p_I1 of the second preliminary transmissive layer TL2p may be inclined to the first flat surface TL2p_B1. The third inclined surface TL2p_I3 of the second preliminary transmissive layer TL2p may be inclined to the second flat surface TL2p_B2.

Referring to FIG. 2L, a second preliminary reflection layer RL2p may be formed on the first and third inclined surfaces TL2p_I1 and TL2p_I3 of the second preliminary transmissive layer TL2p.

Referring to FIG. 2M, a cutting process may be performed on the second preliminary transmissive layer TL2p and the second preliminary reflection layer RL2p. The second preliminary transmissive layer TL2p and the second preliminary reflection layer RL2p may cut along a second cutting line CL2.

Referring to FIG. 2N, the second transmissive layer TL2 and the second reflection layer RL2 may be respectively defined by performing the cutting process on the second preliminary transmissive layer TL2p and the second preliminary reflection layer RL2p.

The second preliminary transmission structure TM2p may be provided on the optical adhesive layer OB. The second inclined surface TL2p_I2 and the top surface TL2p_T of the second preliminary transmissive layer TL2p may be in contact with the optical adhesive layer OB.

Referring to FIG. 2O, the second waveguide WG2 and the third waveguide WG3 may be formed.

In one or more embodiments, the first transmissive layer TL1, the second transmissive layer TL2, the second waveguide WG2, and the third waveguide WG3 may include glass, and the formation of the second and third waveguides WG2 and WG3 may include performing a laser direct writing process. For example, the first transmissive layer TL1 may be irradiated with a laser beam, and a portion of the first transmissive layer TL1 irradiated with the laser beam may have a changed crystal structure and a changed refractive index. For example, the second transmissive layer TL2 may be irradiated with a laser beam, and a portion of the second transmissive layer TL2 irradiated with the laser beam may have a changed crystal structure and a changed refractive index. The portion of the first transmissive layer TL1 irradiated with the laser beam may be defined as the second waveguide WG2, and the portion of the second transmissive layer TL2 irradiated with the laser beam may be defined as the third waveguide WG3.

In one or more embodiments, the formation of the second and third waveguides WG2 and WG3 may include etching the first and second transmissive layers TL1 and TL2 and depositing a SiN layer on the etched first and second transmissive layers TL1 and TL2 to form the second and third waveguides WG2 and WG3.

In one or more embodiments, the formation of the second waveguide WG2 may be performed before providing the first preliminary transmission structure TM1p on the upper bonding layer UB. In one or more embodiments, the formation of the third waveguide WG3 may be performed before providing the second preliminary transmission structure TM2p on the optical adhesive layer OB.

The first preliminary transmission structure TM1p, on which the second waveguide WG2 is formed, may be defined as the first transmission structure TM1. The second preliminary transmission structure TM2p, on which the third waveguide WG3 is formed, may be defined as the second transmission structure TM2. A first flat surface TM2p_B1 of the second preliminary transmission structure TM2p may be defined as a top surface TM2_T of the second transmission structure TM2.

Referring to FIG. 2P, the base substrate GL and the adhesive layer AD may be removed.

Referring to FIGS. 1A, 1B, 1C, 1D, 1E, and 1F, the first solder ball 110, the package substrate 100, the first under-fill layer 220, the second solder ball 210, the connection substrate 200, first connection via 270, the first mold layer 260, the first stack 230, the second stack 240, the third semiconductor chip 250, and the second under-fill layer 320 may be formed. The optical structure 300 may be provided on the package substrate 100.

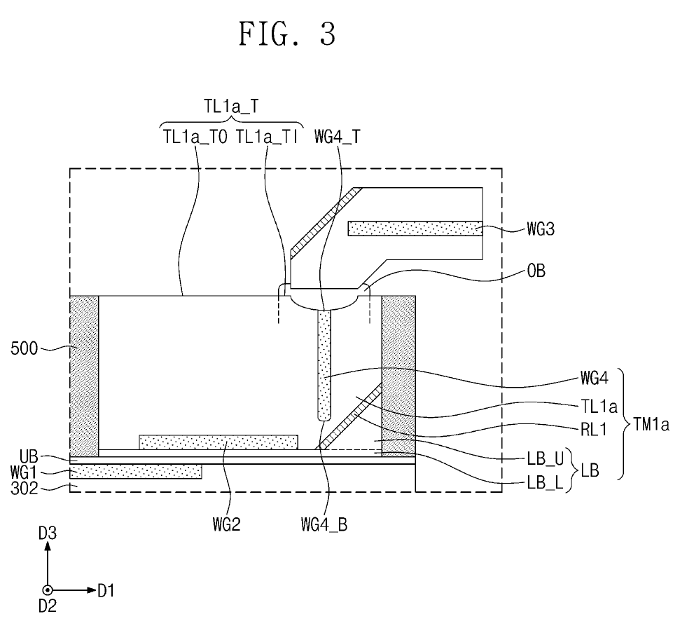

FIG. 3 is an enlarged view illustrating a semiconductor package according to one or more embodiments of the disclosure. The semiconductor package of FIG. 3 may be similar to the semiconductor package described with reference to FIGS. 1A, 1B, 1C, 1D, 1E, and 1F, except for features to be described below.

Referring to FIG. 3, a first transmission structure TM1a may further include a fourth waveguide WG4. The fourth waveguide WG4 may be extended in the third direction D3. The fourth waveguide WG4 may be disposed between the second and third waveguides WG2 and WG3. The fourth waveguide WG4 may be spaced apart from the second and third waveguides WG2 and WG3 in the first direction D1 and the third direction D3. In one or more examples, the fourth wave guide WG4 may be spaced apart from the second waveguide WG2 and the third waveguide WG3 in the first direction D1 by an equal amount. In one or more examples, the fourth wave guide WG4 may be spaced apart from the second waveguide WG2 and the third waveguide WG3 in the first direction D1 by different amounts. In one or more examples, the fourth wave guide WG4 may be spaced apart from the second waveguide WG2 and the third waveguide WG3 in the third direction D3 by an equal amount. In one or more examples, the fourth wave guide WG4 may be spaced apart from the second waveguide WG2 and the third waveguide WG3 in the third direction D1 by different amounts. The fourth waveguide WG4 may not be overlapped with the second and third waveguides WG2 and WG3. The fourth waveguide WG4 may be overlapped with the first reflection layer RL1 in the third direction D3. The fourth waveguide WG4 may be spaced apart from the first reflection layer RL1. The fourth waveguide WG4 may be spaced apart from the first reflection layer RL1.

A first transmissive layer TL1a may be provided to enclose the fourth waveguide WG4. The first transmissive layer TL1a may be in contact with a side surface and a bottom surface WG4_B of the fourth waveguide WG4. A top surface WG4_T and the bottom surface WG4_B of the fourth waveguide WG4 may have a curved portion. The top surface WG4_T of the fourth waveguide WG4 may be in contact with the optical adhesive layer OB.

The top surface WG4_T of the fourth waveguide WG4 may be coplanar with an inner portion TL1a_TI of a top surface TL1a_T of the first transmissive layer TL1a. The top surface WG4_T of the fourth waveguide WG4 may be coplanar with a curved surface of the inner portion TL1a_TI of the top surface TL1a_T of the first transmission layer TL1a.

The fourth waveguide WG4 may include the same material as the second and third waveguides WG2 and WG3. For example, the fourth waveguide WG4 may include SiN or glass whose crystal structure and refractive index are changed by a laser direct writing method.

In the semiconductor package according to one or more embodiments of the disclosure, since the fourth waveguide extending in the third direction D3 is provided, it may be possible to increase the optical transmittance between the second and third waveguides WG2 and WG3.

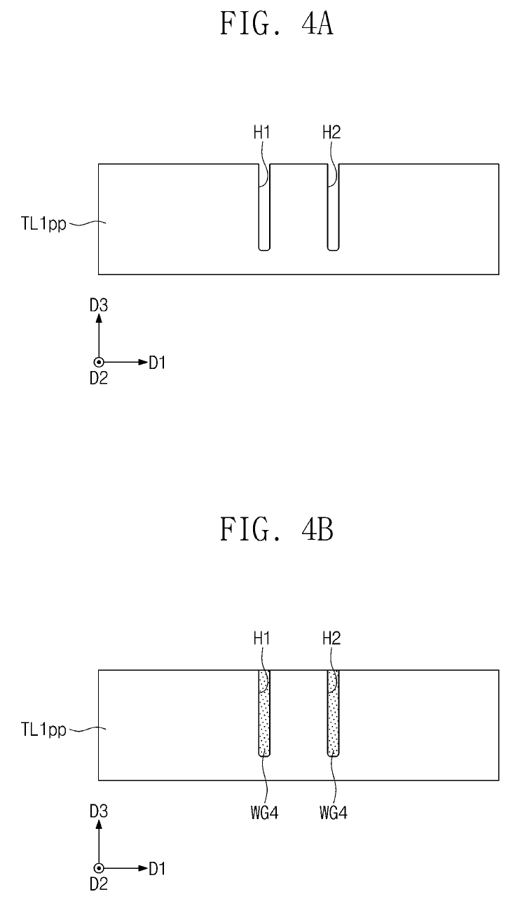

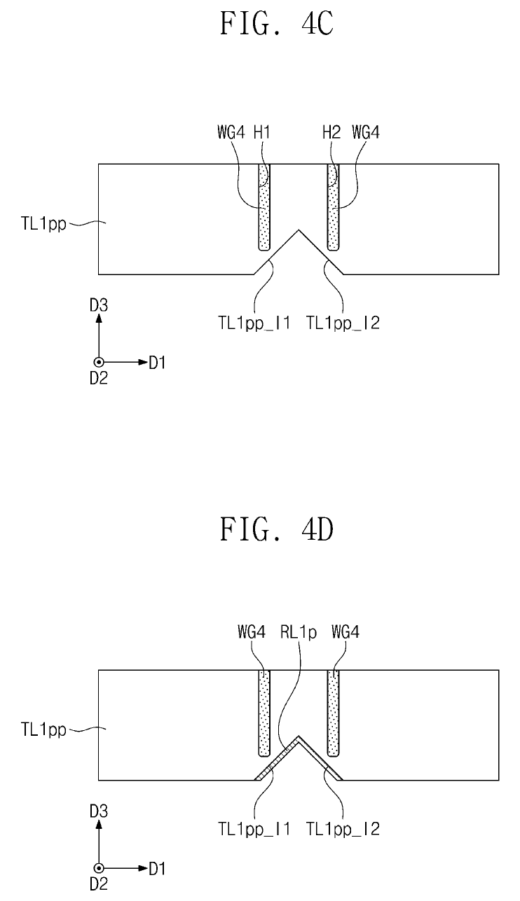

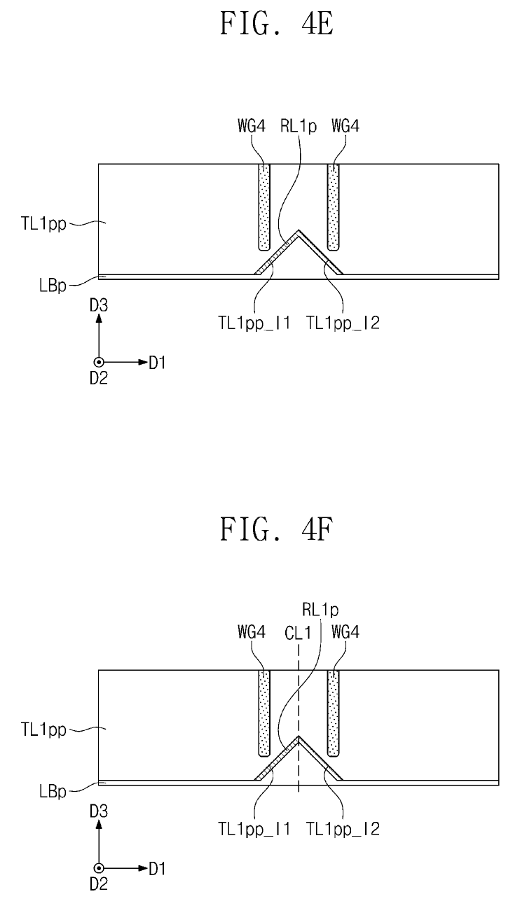

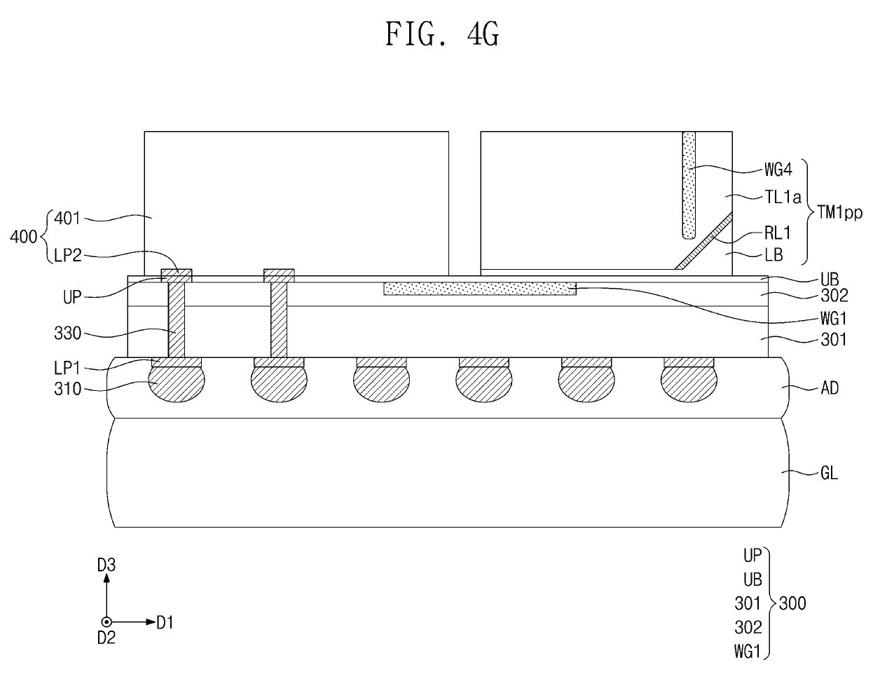

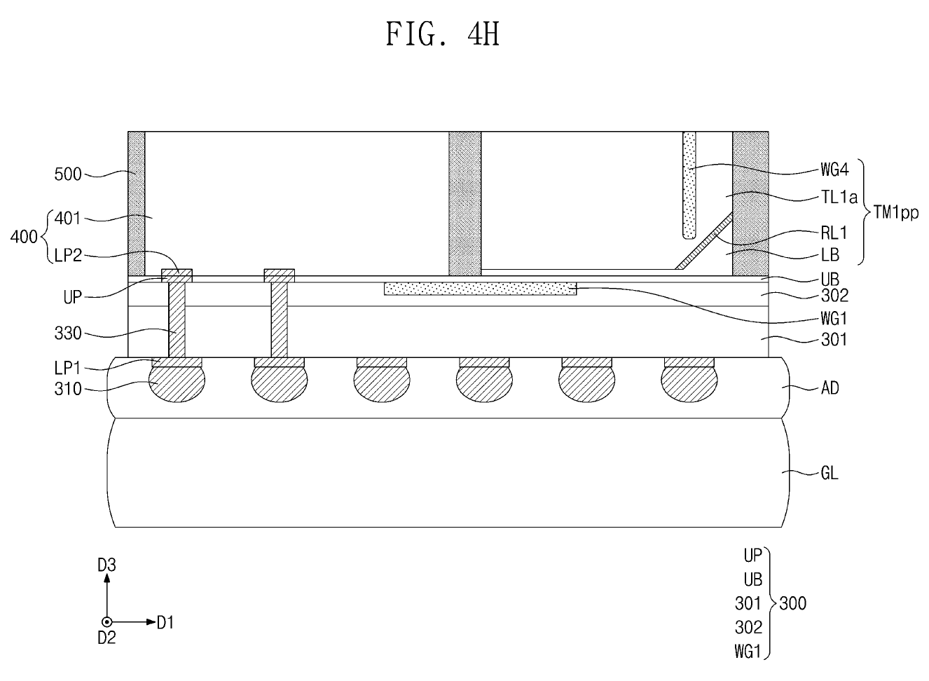

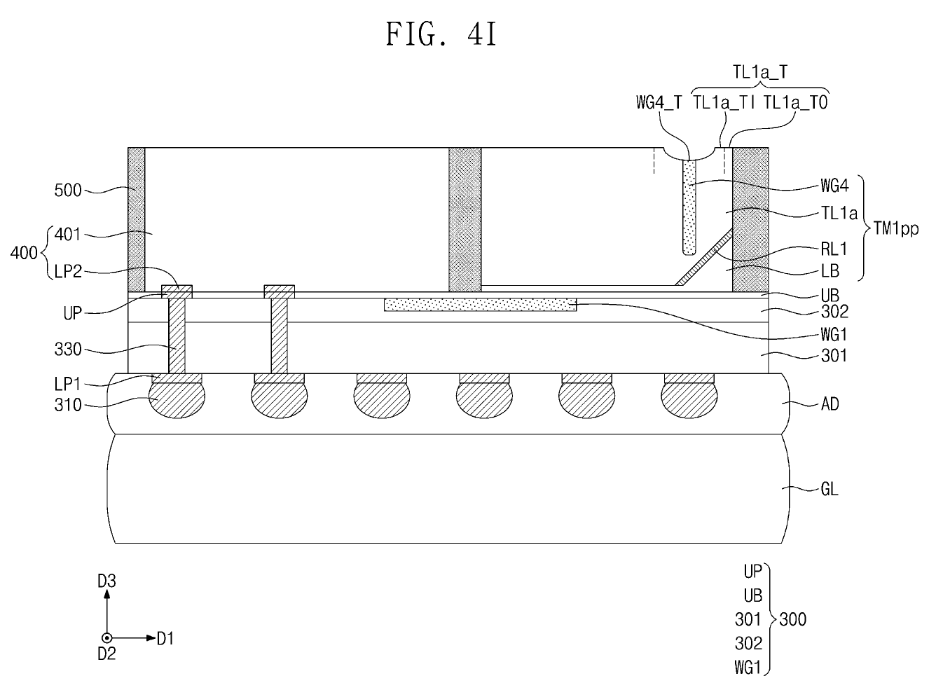

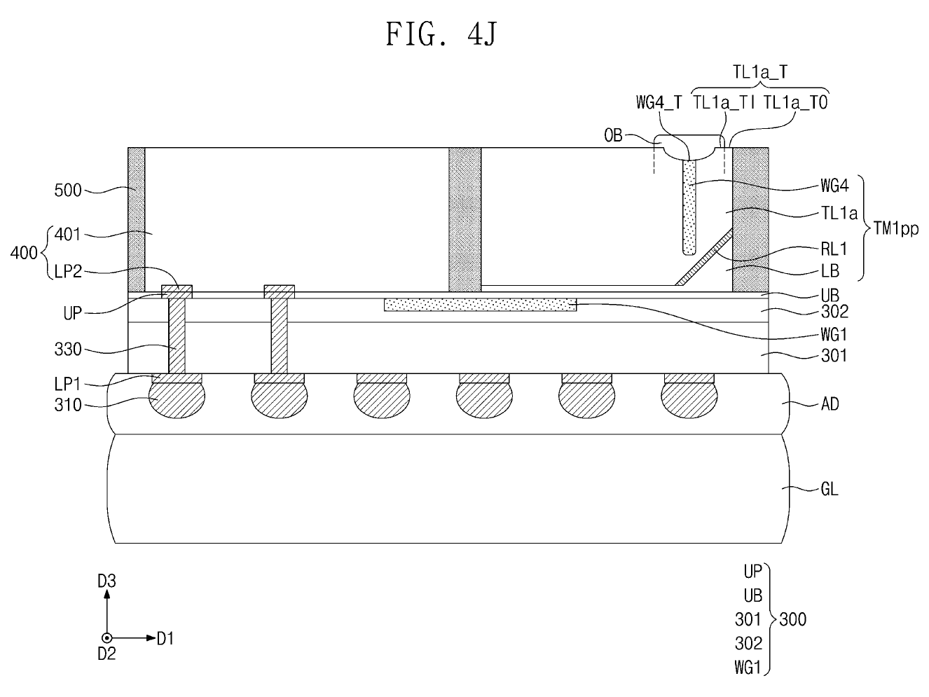

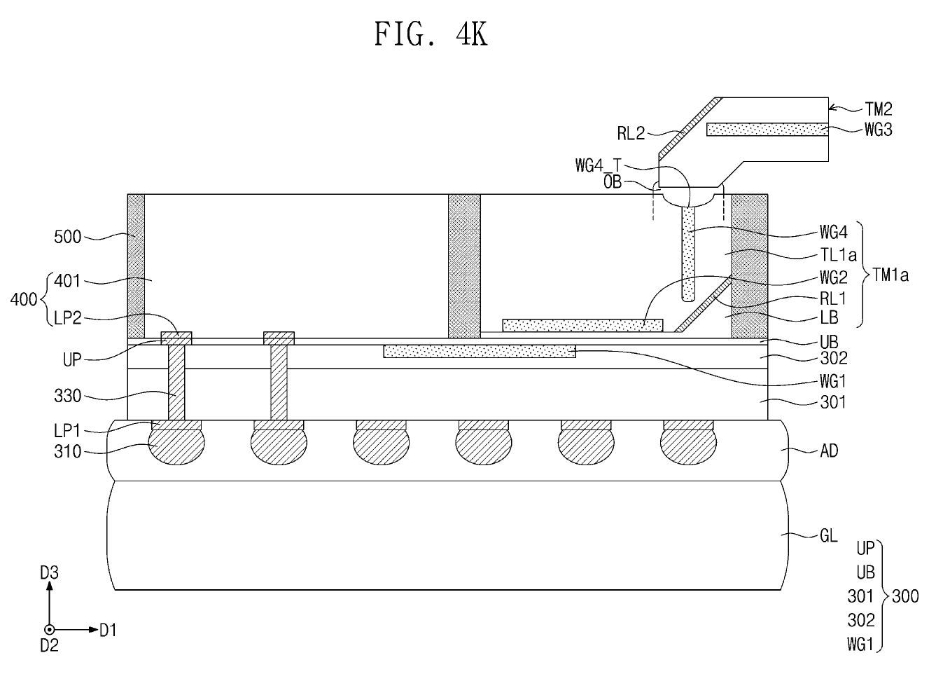

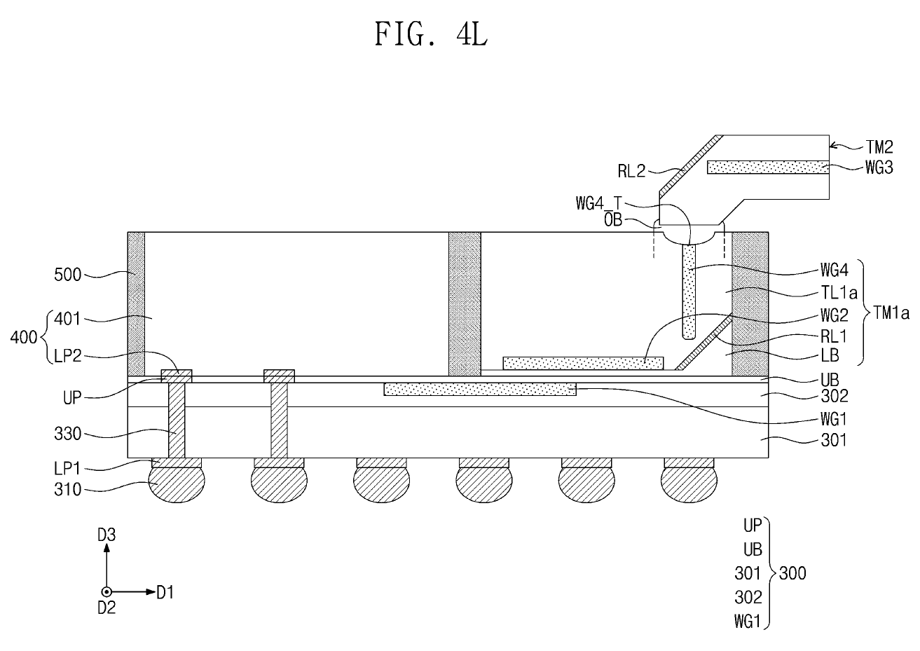

FIGS. 4A, 4B, 4C, 4D, 4E, 4F, 4G, 4H, 4I, 4J, 4K, and 4L are diagrams illustrating a method of fabricating the semiconductor package of FIG. 3. This fabrication method may be similar to the method described with reference to FIGS. 2A, 2B, 2C, 2D, 2E, 2F, 2G, 2H, 2I, 2J, 2K, 2L, 2M, 2N, 2O, and 2P, except for features to be described below.

Referring to FIG. 4A, a first preliminary transmissive layer TL1pp may be provided. A first hole H1 and a second hole H2 may be formed in the first preliminary transmissive layer TL1pp. The formation of the first and second holes H1 and H2 may include performing an etching process.

Referring to FIG. 4B, fourth waveguides WG4 may be formed in the first and second holes H1 and H2. The formation of the fourth waveguide WG4 may include performing a chemical vapor deposition (CVD) process.

Referring to FIG. 4C, a first inclined surface TL1pp_I1 and a second inclined surface TL1pp_I2 may be formed by etching the first preliminary transmissive layer TL1pp.

Referring to FIG. 4D, the first preliminary reflection layer RL1p may be formed.

Referring to FIG. 4E, the preliminary lower bonding layer LBp may be formed.

Referring to FIG. 4F, a cutting process may be performed on the first preliminary reflection layer RL1p, the preliminary lower bonding layer LBp, and the first preliminary transmissive layer TL1pp. The first preliminary reflection layer RL1p, the preliminary lower bonding layer LBp, and the first preliminary transmissive layer TL1pp may be cut along the first cutting line CL1.

Referring to FIG. 4G, the first reflection layer RL1, the lower bonding layer LB, and the first transmissive layer TL1a may be respectively defined by performing the cutting process on the first preliminary reflection layer RL1p, the preliminary lower bonding layer LBp, and the first preliminary transmissive layer TL1pp. A first preliminary transmission structure TM1pp may include the first reflection layer RL1, the lower bonding layer LB, and the first transmissive layer TL1a. The first transmission structure TM1a may be provided on the upper bonding layer UB.

Referring to FIG. 4H, the second mold layer 500 may be formed.

Referring to FIG. 4I, the first transmissive layer TL1a and the fourth waveguide WG4 may be partially removed. The partial removal of the first transmissive layer TL1a and the fourth waveguide WG4 may include an etching process. As a result of the partial removal of the first transmissive layer TL1a and the fourth waveguide WG4, a portion of the inner portion TL1a_TI of the top surface TL1a_T of the first transmissive layer TL1a and the top surface WG4_T of the fourth waveguide WG4 may be formed to have a curved shape.

Referring to FIG. 4J, the optical adhesive layer OB may be formed.

Referring to FIG. 4K, the second transmission structure TM2 may be disposed on the optical adhesive layer OB. The second waveguide WG2 may be formed on the first transmissive layer TL1a. The formation of the second waveguide WG2 may include performing a laser direct writing process. The first preliminary transmission structure TM1pp provided with the second waveguide WG2 may be defined as the first transmission structure TM1a.

Referring to FIG. 4L, the base substrate GL and the adhesive layer AD may be removed.

Referring to FIGS. 1A, 1B, 1D, 1E, 1F, and 3, the first solder ball 110, the package substrate 100, the first under-fill layer 220, the second solder ball 210, the connection substrate 200, first connection via 270, the first mold layer 260, the first stack 230, the second stack 240, the third semiconductor chip 250, and the second under-fill layer 320 may be formed. The optical structure 300 may be provided on the package substrate 100.

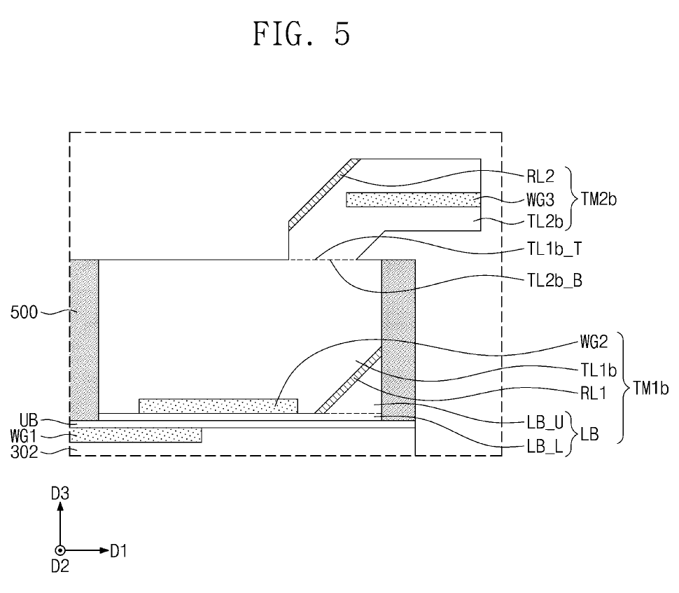

FIG. 5 is an enlarged view illustrating a semiconductor package according to one or more embodiments of the disclosure. The semiconductor package of FIG. 5 may be similar to the semiconductor package described with reference to FIGS. 1A, 1B, 1C, 1D, 1E, and 1F, except for features to be described below.

Referring to FIG. 5, a first transmission structure TM1b may include the lower bonding layer LB, the second waveguide WG2, the first reflection layer RL1, and a first transmissive layer TL1b. A second transmission structure TM2b may include the second reflection layer RL2, the third waveguide WG3, and a second transmissive layer TL2b.

The first and second transmissive layers TL1b and TL2b may be in contact with each other. A top surface TL1b_T of the first transmissive layer TL1b and a bottom surface TL2b_B of the second transmissive layer TL2b may be in contact with each other. The first and second transmissive layers TL1b and TL2b may be connected to each other to form a single object without any interface therebetween. The first and second transmissive layers TL1b and TL2b may be connected to each other without any interface therebetween through a laser welding process.

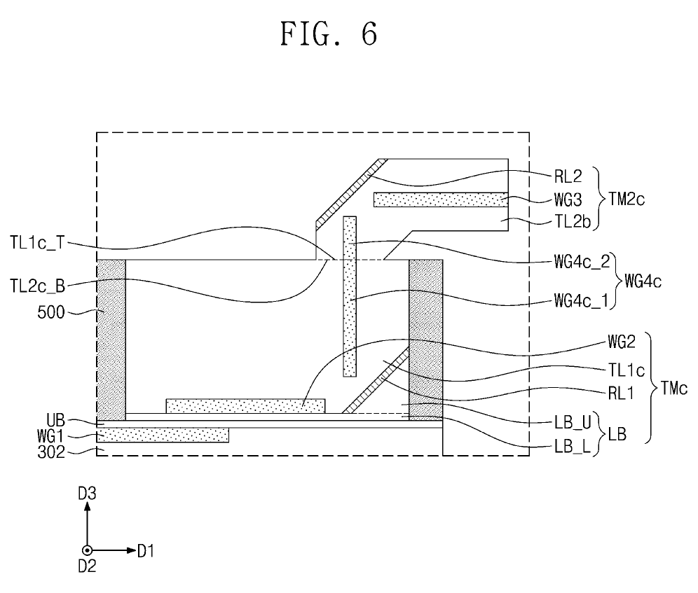

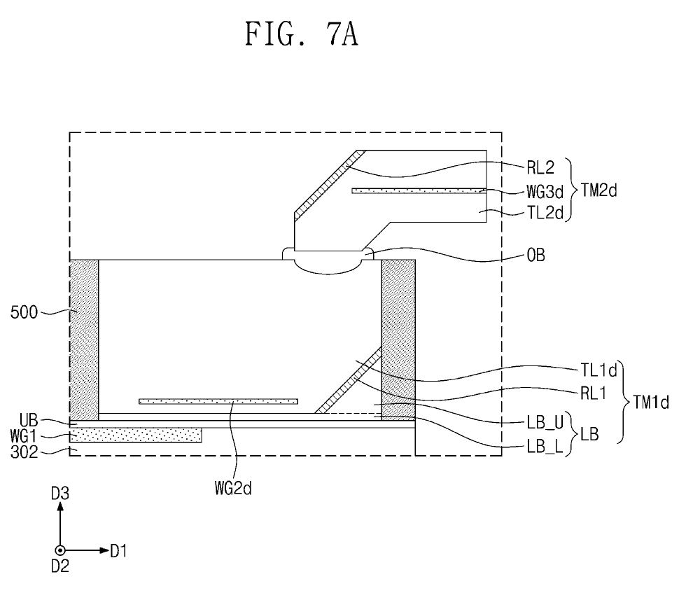

FIG. 6 is an enlarged view illustrating a semiconductor package according to one or more embodiments of the disclosure. The semiconductor device of FIG. 6 may be similar to the semiconductor package described with reference to FIGS. 3 and 5, except for features to be described below.

Referring to FIG. 6, a first transmission structure TM1c may include the lower bonding layer LB, the second waveguide WG2, the first reflection layer RL1, and a first transmissive layer TL1c. A second transmission structure TM2c may include the second reflection layer RL2, the third waveguide WG3, and a second transmissive layer TL2c. The first transmissive layer TL1c may include a top surface TL1c_T. The second transmissive layer TL2c may include a bottom surface TL2c_B.

A fourth waveguide WG4c may be provided to penetrate the top surface TL1c_T of the first transmissive layer TL1c and the bottom surface TL2c_B of the second transmissive layer TL2c. The fourth waveguide WG4c may be extended in the third direction D3. The fourth waveguide WG4c may include a first region WG4c_1 in contact with the first transmissive layer TL1c and a second region WG4c_2 in contact with the second transmissive layer TL2c. The first region WG4c_1 of the fourth waveguide WG4c may be disposed at a level lower than the top surface TL1c_T of the first transmissive layer TL1c. The second region WG4c_2 of the fourth waveguide WG4c may be disposed at a level lower than the bottom surface TL2c_B of the second transmissive layer TL2c.

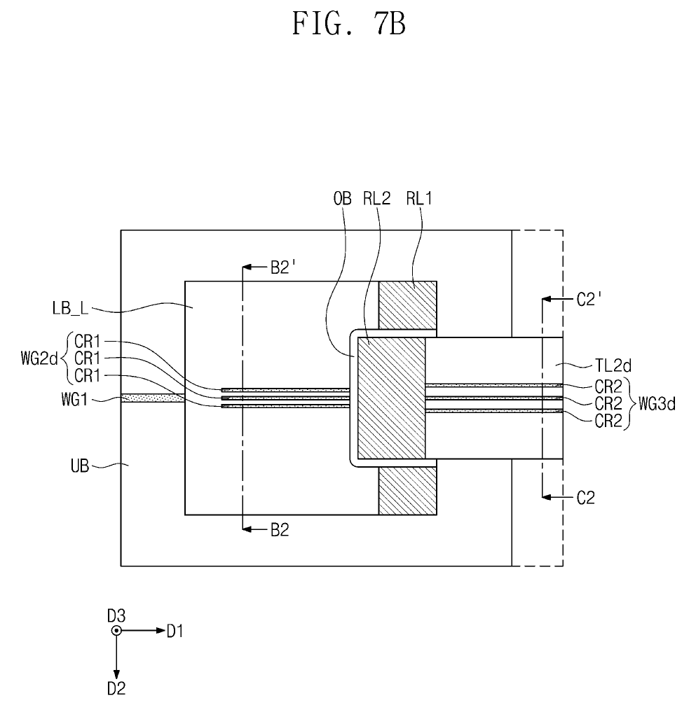

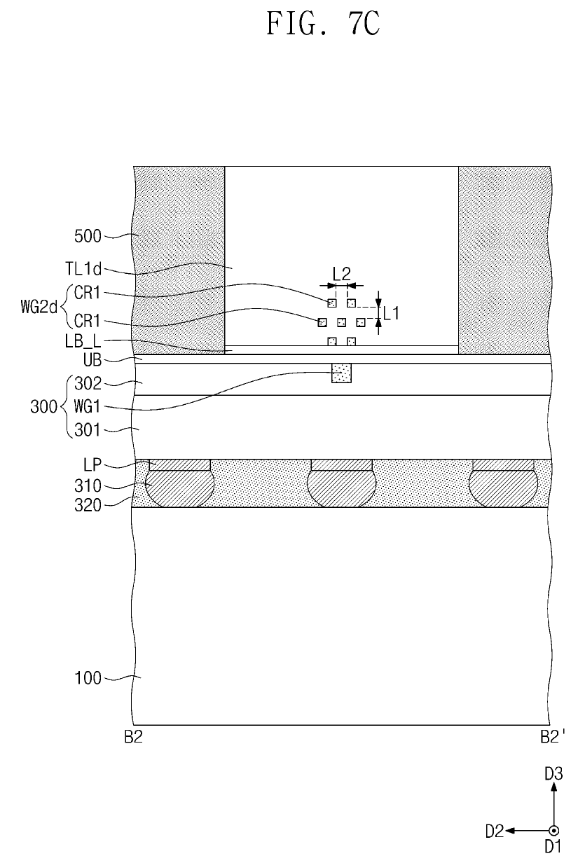

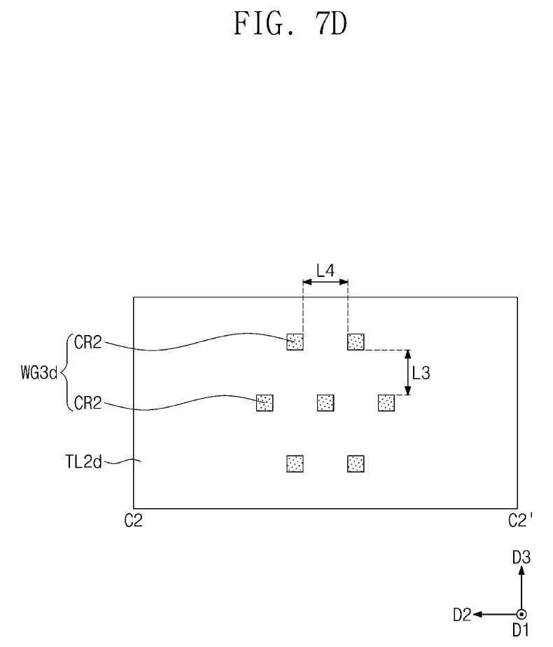

FIGS. 7A, 7B, 7C, and 7D are diagrams illustrating a semiconductor package according to one or more embodiments of the disclosure. FIG. 7C is a sectional view taken along a line B2-B2’ of FIG. 7B. FIG. 7D is a sectional view taken along a line C2-C2’ of FIG. 7B. The semiconductor package of FIGS. 7A, 7B, 7C, and 7D may be similar to the semiconductor package described with reference to FIGS. 1A, 1B, 1C, 1D, 1E, and 1F, except for features to be described below.

Referring to FIGS. 7A, 7B, 7C, and 7D, a second waveguide WG2d may include a plurality of first cores CR1. The first core CR1 may be extended in the first direction D1. A third waveguide WG3d may include a plurality of second cores CR2. The second core CR2 may be extended in the first direction D1.

When viewed in the sectional view of FIG. 7C, the first cores CR1 may be arranged in a hexagonal shape. The first cores CR1 may be spaced apart from each other. A first transmissive layer TL1d may be provided to enclose each of the first cores CR1. When viewed in the sectional view of FIG. 7C, the second cores CR2 may be arranged in a hexagonal shape. The second cores CR2 may be spaced apart from each other. The second transmissive layer TL2d may be provided to enclose the second cores CR2, respectively. The lowermost ones of the first cores CR1 may be in contact with the lower portion LB_L of the lower bonding layer LB. When viewed in the sectional view of FIG. 7C, an area of each of the first and second cores CR1 and CR2 may be smaller than an area of the first waveguide WG1.

A distance L1 between the first cores CR1, which are adjacent to each other in the third direction D3, may be smaller than a distance L3 between the second cores CR2, which are adjacent to each other in the third direction D3. A distance L2 between the first cores CR1, which are adjacent to each other in the second direction D2, may be smaller than a distance L4 between the second cores CR2, which are adjacent to each other in the second direction D2.

In the semiconductor package according to one or more embodiments of the disclosure, a distance between adjacent ones of the first cores CR1 may be smaller than a distance between adjacent ones of the second cores CR2. Thus, even in the case where the first waveguide WG1 has a relatively small sectional area, light may be easily transmitted to the first cores CR1. Accordingly, it may be possible to place the first waveguide WG1 with a relatively small sectional area and to increase an integration density of optical devices in the optical structure 300.

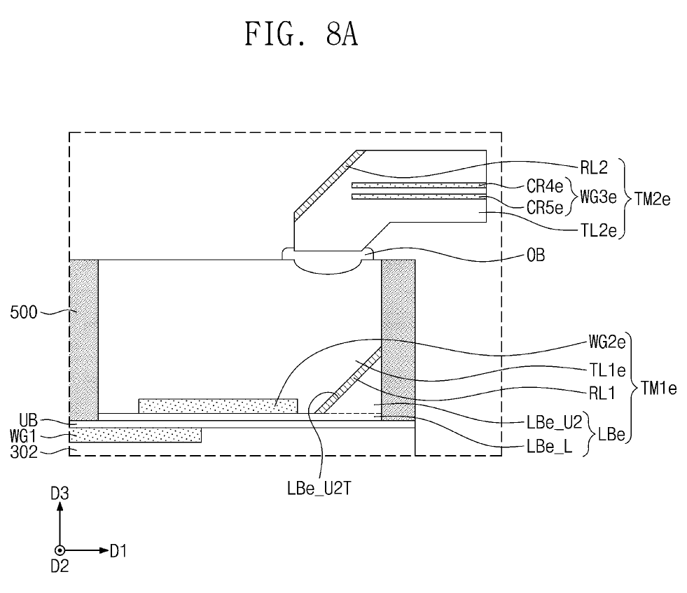

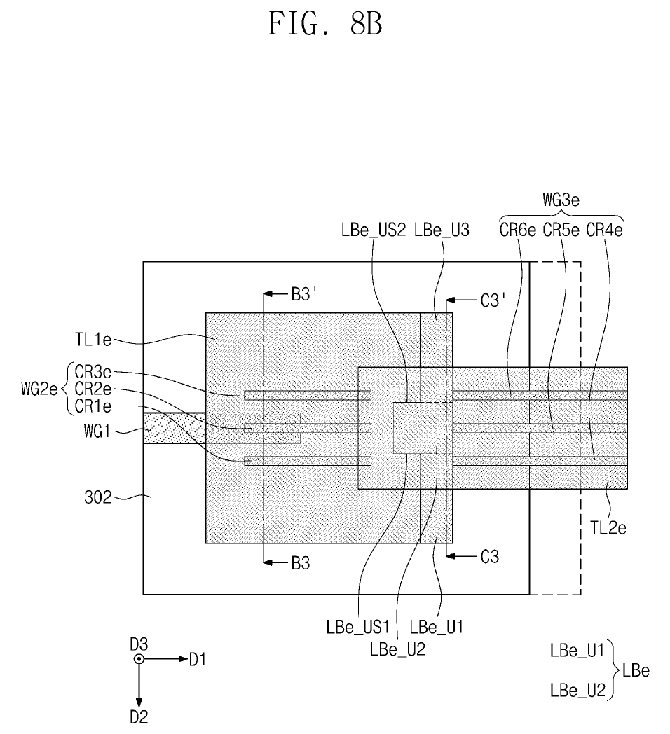

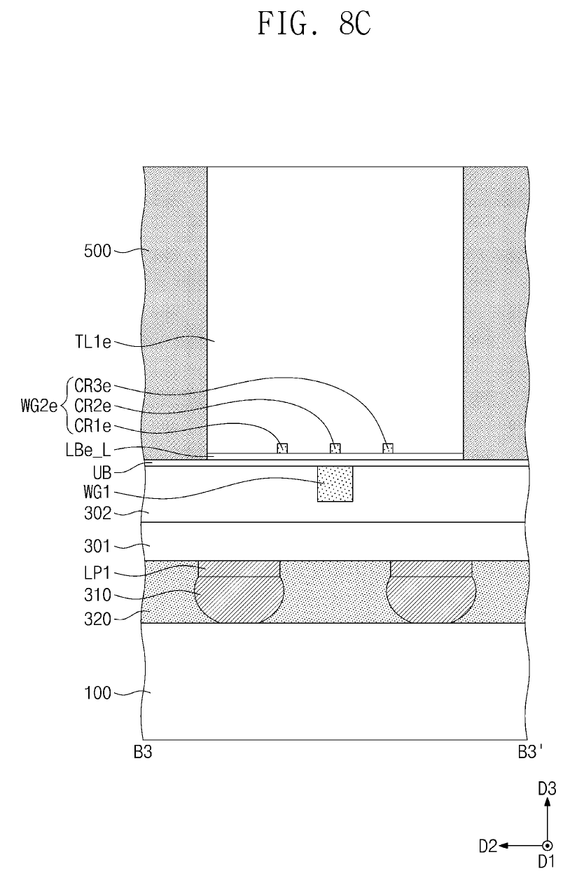

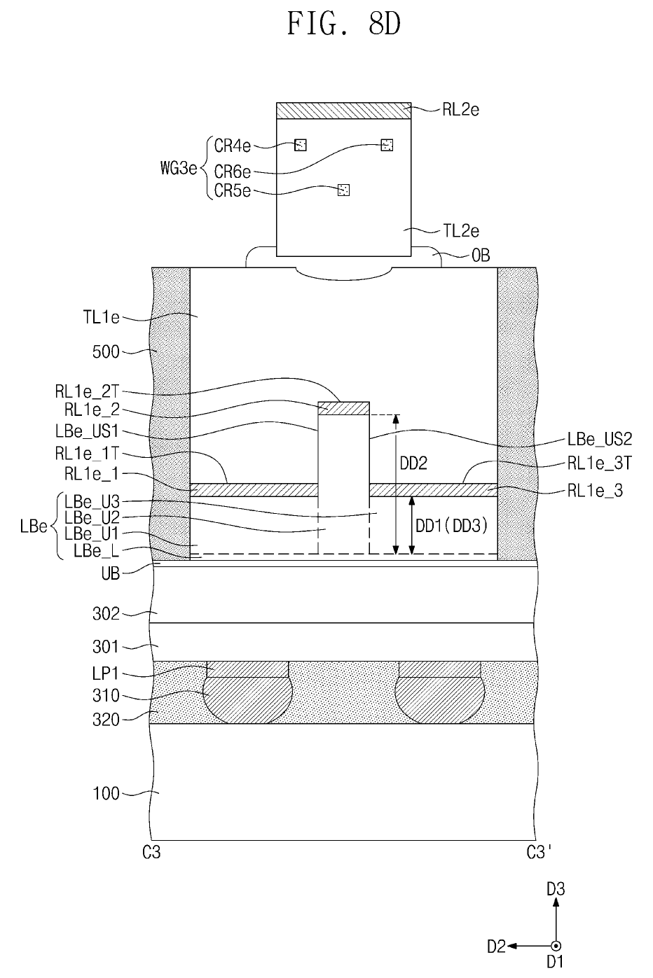

FIGS. 8A, 8B, 8C, and 8D are diagrams illustrating a semiconductor package according to one or more embodiments of the disclosure. FIG. 8C is a sectional view taken along a line B3-B3’ of FIG. 8B. FIG. 8D is a sectional view taken along a line C3-C3’ of FIG. 8B. The semiconductor package of FIGS. 8A, 8B, 8C, and 8D may be similar to the semiconductor package described with reference to FIGS. 7A, 7B, 7C, and 7D, except for features to be described below.

Referring to FIGS. 8A, 8B, 8C, and 8D, the lower bonding layer LBe may include a lower portion LBe_L and an upper portion, which includes a first portion LBe_U1, a second portion LBe_U2, and a third portion LBe_U3. The first portion LBe_U1 and the third portion LBe_U3 of the upper portion of the lower bonding layer LBe may be spaced apart from each other in the second direction D2. The second portion LBe_U2 of the upper portion of the lower bonding layer LBe may be disposed between the first portion LBe_U1 and the third portion LBe_U3.

The second portion LBe_U2 of the upper portion of the lower bonding layer LBe may include a first side surface LBe_US1 connected to the first portion LBe_U1 and a second side surface LBe_US2 connected to the third portion LBe_U3. The first side surface LBe_US1 and the second side surface LBe_US2 of the second portion LBe_U2 of the upper portion of the lower bonding layer LBe may be spaced apart from each other in the second direction D2.

Top surfaces LBe_U1T, LBe_U2T, and LBe_U3T of the first, second, and third portions LBe_U1, LBe_U2, and LBe_U3 of the upper portion of the lower bonding layer LBe may be connected to a top surface of the lower portion LBe_L of the lower bonding layer LBe. The top surfaces LBe_U1T, LBe_U2T, and LBe_U3T of the first, second, and third portions LBe_U1, LBe_U2, and LBe_U3 of the upper portion of the lower bonding layer LBe may be inclined to the top surface of the lower portion LBe_L of the lower bonding layer LBe. The top surfaces LBe_U1T, LBe_U2T, and LBe_U3T of the first, second, and third portions LBe_U1, LBe_U2, and LBe_U3 of the upper portion of the lower bonding layer LBe may be spaced apart from each other.

The largest value DD2 of a thickness of the second portion LBe_U2 of the upper portion of the lower bonding layer LBe in the third direction D3 may be larger than the largest value DD1 of a thickness of the first portion LBe_U1 of the upper portion of the lower bonding layer LBe in the third direction D3 and the largest value DD3 of a thickness of the third portion LBe_U3 of the upper portion of the lower bonding layer LBe in the third direction D3. The largest value DD1 of the thickness of the first portion LBe_U1 of the upper portion of the lower bonding layer LBe in the third direction D3 may be equal to the largest value DD3 of the thickness of the third portion LBe_U3 of the upper portion of the lower bonding layer LBe in the third direction D3.

A first reflection layer RL1e may include a first portion RL1e_1 in contact with the first portion LBe_U1 of the upper portion of the lower bonding layer LBe, a second portion RL1e_2 in contact with the second portion LBe_U2 of the upper portion of the lower bonding layer LBe, and a third portion RL1e_3 in contact with the third portion LBe_U3 of the upper portion of the lower bonding layer LBe.

The first portion RL1e_1 of the first reflection layer RL1e may be in contact with the first side surface LBe_US1 of the second portion LBe_U2 of the upper portion of the lower bonding layer LBe. The third portion RL1e_3 of the first reflection layer RL1e may be in contact with the second side surface LBe_US2 of the second portion LBe_U2 of the upper portion of the lower bonding layer LBe.

The first portion RL1e_1, the second portion RL1e_2, and the third portion RL1e_3 of the first reflection layer RL1e may be spaced apart from each other. The largest value of a distance between the second portion RL1e_2 of the first reflection layer RL1e and the lower portion LBe_L of the lower bonding layer LBe may be larger than the largest value of a distance between the first portion RL1e_1 of the first reflection layer RL1e and the lower portion LBe_L of the lower bonding layer LBe and the largest value of a distance between the third portion RL1e_3 of the first reflection layer RL1e and the lower portion LBe_L of the lower bonding layer LBe.

A top surface RL1e_1T of the first portion RL1e_1, a top surface RL1e_2T of the second portion RL1e_2, and a top surface RL1e_3T of the third portion RL1e_3 of the first reflection layer RL1e may be inclined to the top surface of the upper bonding layer UB.

The second waveguide WG2e may include a first core CR1e, a second core CR2e, and a third core CR3e. The third waveguide WG3e may include a fourth core CR4e, a fifth core CR5e, and a sixth core CR6e. The first to sixth cores CR1e, CR2e, CR3e, CR4e, CR5e, and CR6e may include the same material. The first to sixth cores CR1e, CR2e, CR3e, CR4e, CR5e, and CR6e may include the same material as the first waveguide WG1.

The first core CR1e, the second core CR2e, and the third core CR3e may be arranged in the second direction D2. The first core CR1e, the second core CR2e, and the third core CR3e may be disposed at the same level.

The second core CR2e may be disposed between the first core CR1e and the third core CR3e. The first core CR1e may be overlapped with the first portion RL1e_1 of the first reflection layer RL1e in the third direction D3. The second core CR2e may be overlapped with the second portion RL1e_2 of the first reflection layer RL1e in the third direction D3. The third core CR3e may be overlapped with the third portion RL1e_3 of the first reflection layer RL1e in the third direction D3.

The fourth and sixth cores CR4e and CR6e may be disposed to form a triangle shape, when viewed in the sectional view of FIG. 8D. The fourth and sixth cores CR4e and CR6e may be disposed at a level higher than the fifth core CR5e.

The fourth core CR4e may be overlapped with the first portion RL1e_1 of the first reflection layer RL1e in the third direction D3. The fifth core CR5e may be overlapped with the second portion RL1e_2 of the first reflection layer RL1e in the third direction D3. The sixth core CR6e may be overlapped with the third portion RL1e_3 of the first reflection layer RL1e in the third direction D3.

In the semiconductor package according to one or more embodiments of the disclosure, the upper portion of the lower bonding layer LBe may include the first LBe_U1, the second portion LBe_U2, and the third portion LBe_U3, and light rays, which are emitted from the first, second, and third cores CR1e, CR2e, and CR3e, may be respectively reflected from the first, second, and third portions RL1e_1, RL1e_2 , and RL1e_3 which are spaced apart from each other in the first direction D1. Thus, light rays, which are reflected from the second reflection layer RL2, may be spaced apart from each other in the third direction D3. Accordingly, all of the first to third cores CR1e, CR2e, and CR3e of the second waveguide WG2e may be disposed to be in contact with the lower bonding layer LBe, and it may be possible to reduce an optical loss issue between the first and second waveguides WG1 and WG2e.

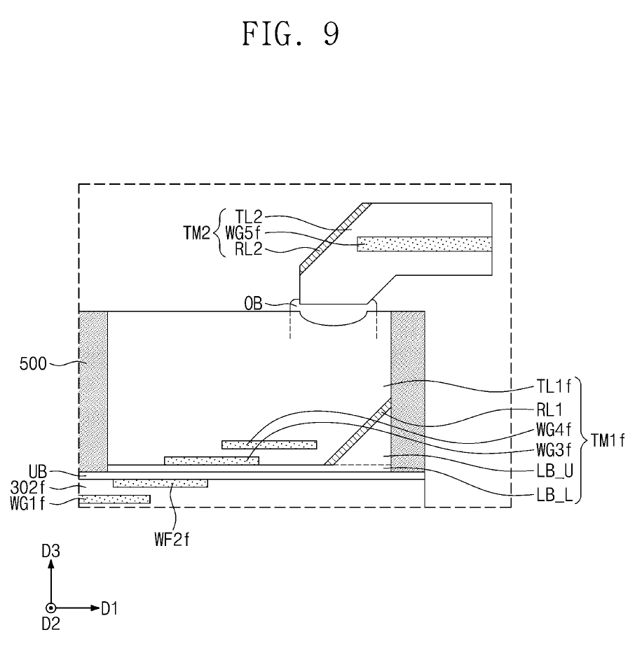

FIG. 9 is an enlarged view illustrating a semiconductor package according to one or more embodiments of the disclosure. The semiconductor package of FIG. 9 may be similar to the semiconductor package described with reference to FIGS. 1A to 1F, except for features to be described below.

Referring to FIG. 9, the optical structure 300 may include a first waveguide WG1f and a second waveguide WG2f. The first waveguide WG1f may be enclosed by an optical path layer 302f. The second waveguide WG2f may be disposed on the optical path layer 302f. The second waveguide WG2f may be in contact with the upper bonding layer UB.

A portion of the first waveguide WG1f and a portion of the second waveguide WG2f may be overlapped with each other in the third direction D3. The first and second waveguides WG1f and WG2f may be spaced apart from each other in the third direction D3. A portion of the optical path layer 302f may be disposed between the first and second waveguides WG1f and WG2f.

The first transmission structure TM1f may include a third waveguide WG3f and a fourth waveguide WG4f. The fourth waveguide WG4f may be enclosed by the first transmissive layer TL1f. The third waveguide WG3f may be in contact with the lower portion LB_L of the lower bonding layer LB.

A portion of the third waveguide WG3f and a portion of the fourth waveguide WG4f may be overlapped with each other in the third direction D3. The third and fourth waveguides WG3f and WG4f may be spaced apart from each other in the third direction D3. A portion of the first transmissive layer TL1f may be disposed between the third and fourth waveguides WG3f and WG4f.

The third waveguide WG3f may be overlapped with the second waveguide WG2f in the third direction D3. The second waveguide WG2f and the third waveguide WG3f may be spaced apart from each other in the third direction D3. The upper bonding layer UB and the lower portion LB_L of the lower bonding layer LB may be disposed between the second waveguide WG2f and the third waveguide WG3f.

The second transmission structure TM2 may include a fifth waveguide WG5f. The fifth waveguide WG5f may be similar to the third waveguide WG3 of the semiconductor package of FIG. 1C.

Optical transmission between the first and second waveguides WG1f and WG2f may be achieved through evanescent coupling. Optical transmission between the third and fourth waveguides WG3f and WG4f may be achieved through evanescent coupling.

In a semiconductor package according to one or more embodiments of the disclosure, waveguides, which are overlapped with each other, may be provided, and a lower bonding layer and an upper bonding layer, which are relatively thin, may be formed between the overlapped waveguides. In this case, it may be possible to reduce an optical loss issue between a first waveguide and a second waveguide.

In the semiconductor package according to one or more embodiments of the disclosure, the upper bonding layer and the lower bonding layer may include an inorganic insulating material and may be bonded to each other by a bonding process. Thus, it may be possible to reduce the thicknesses of the bonding layers and a distance between overlapped waveguides. Accordingly, it may be possible to reduce an optical loss caused by the bonding layer.

While example embodiments of the disclosure have been particularly shown and described, it will be understood by one of ordinary skill in the art that variations in form and detail may be made therein without departing from the spirit and scope of the attached claims.

What is claimed is:

1. A semiconductor package comprising:
an optical structure; and
a first transmission structure on the optical structure,
wherein the optical structure comprises a first waveguide extending in a first direction,
wherein the first transmission structure comprises:
a first bonding layer including a first portion and a second portion, and
a second waveguide extending in the first direction,
wherein at least a first portion of the first waveguide overlaps a second portion of the second waveguide,
wherein the second portion of the first bonding layer is between the first waveguide and the second waveguide, and
wherein the first bonding layer comprises a material different from the first waveguide and the second waveguide.

2. The semiconductor package of claim 1, wherein a surface of the first portion of the first bonding layer is inclined towards a surface of the second portion of the first bonding layer.

3. The semiconductor package of claim 1, wherein the optical structure further comprises a second bonding layer in contact with a surface of the second portion of the first bonding layer,
wherein the second bonding layer is between the first waveguide and the second waveguide, and
wherein the first bonding layer and the second bonding layer comprise a same material.

4. The semiconductor package of claim 1, further comprising a second transmission structure overlapped with the first transmission structure,
wherein the second transmission structure comprises a third waveguide extending in the first direction, and
wherein the third waveguide is not overlapped with the first waveguide and the second waveguide.

5. The semiconductor package of claim 4, wherein the second waveguide comprises a plurality of first cores,
wherein the third waveguide comprises a plurality of second cores, and
wherein a first distance between adjacent first cores of the plurality of first cores is smaller than a second distance between adjacent second cores of the plurality of second cores when measured in a second direction crossing the first direction.

6. The semiconductor package of claim 4, wherein the first transmission structure further comprises a first transmissive layer surrounding the second waveguide,
wherein the second transmission structure further comprises a second transmissive layer surrounding the third waveguide, and
wherein the first transmissive layer and the second transmissive layer are connected to each other to form a single object.

7. The semiconductor package of claim 6, wherein the first transmissive layer and the second transmissive layer comprise glass.

8. The semiconductor package of claim 4, wherein the first transmission structure further comprises a first transmissive layer surrounding the second waveguide,
wherein a surface of the first transmissive layer comprises an inner portion and an outer portion surrounding the inner portion, and
the inner portion of the surface of the first transmissive layer comprises a curved surface.

9. The semiconductor package of claim 8, further comprising an optical adhesive layer in contact with the inner portion of the surface of the first transmissive layer.

10. The semiconductor package of claim 1, wherein the first portion of the first bonding layer is not overlapped with the first waveguide.

11. A semiconductor package comprising:
an optical structure; and
a first transmission structure on the optical structure,
wherein the optical structure comprises:
a first waveguide extending in a first direction, and
a first bonding layer on the first waveguide,
wherein the first transmission structure comprises:
a second bonding layer in contact with a surface of the first bonding layer,
a second waveguide extending in the first direction, and
a first transmissive layer on the second waveguide,
wherein at least a first portion of the first waveguide and overlaps a second portion of the second waveguide, and
wherein the first bonding layer and the second bonding layer comprise an inorganic insulating material.

12. The semiconductor package of claim 11, wherein the first waveguide and the second waveguide have a same refractive index.

13. The semiconductor package of claim 11, further comprising a second transmission structure overlapped with the first transmission structure,
wherein the second transmission structure comprises a third waveguide extending in the first direction and a second transmissive layer enclosing the third waveguide,
wherein the third waveguide is not overlapped with the first waveguide and the second waveguide,
wherein the second transmissive layer comprises an inclined surface connecting a first surface and a second surface of the second transmissive layer,
wherein the first surface of the second transmissive layer is perpendicular to the second surface of the second transmissive layer, and
wherein the inclined surface of the second transmissive layer is inclined to the second surface of the second transmissive layer.

14. The semiconductor package of claim 11, wherein the second bonding layer comprises a first portion, a second portion, and a third portion, which are arranged in a second direction crossing the first direction, and
wherein a largest width of the second portion of the second bonding layer in the first direction is larger than a largest width of the first portion and the third portion of the second bonding layer in the first direction.

15. The semiconductor package of claim 14, wherein the second portion of the second bonding layer comprises a first surface connecting a second surface of the first portion and a third surface of the second portion of the second bonding layer.

16. A semiconductor package comprising:
a package substrate;
a semiconductor chip on the package substrate;
a first mold layer on the semiconductor chip;
an optical structure on the package substrate;
an electronic circuit structure on the optical structure;
a first transmission structure and a second transmission structure on the optical structure; and
a second mold layer on the electronic circuit structure, the optical structure, and the first transmission structure, the second mold layer spaced apart from the first mold layer,
wherein the optical structure comprises a first waveguide extending in a first direction,
wherein the first transmission structure comprises a second waveguide, which is extended in the first direction and is at a level higher than the first waveguide,
wherein the second transmission structure comprises a third waveguide, which is extended in the first direction and is at a level higher than the second waveguide,
wherein at least a first portion of the first waveguide overlaps a second portion of the second waveguide, and
wherein the third waveguide is spaced apart from the second waveguide in the first direction.

17. The semiconductor package of claim 16, wherein the second waveguide and the third waveguide are not overlapped with each other.

18. The semiconductor package of claim 16, wherein the first transmission structure comprises a first reflection layer,
wherein the second transmission structure comprises a second reflection layer,
wherein a surface of the first reflection layer and a surface of the second reflection layer are inclined to a surface of the optical structure, and
wherein the first reflection layer and the second reflection layer comprise a material having a refractive index ranging from 1 to 2.

19. The semiconductor package of claim 16, further comprising a fourth waveguide extending in a second direction crossing the first direction,
wherein the fourth waveguide is between the second waveguide and the third waveguide.

20. The semiconductor package of claim 19, wherein the first to fourth waveguides comprise SiN.
